(19) United States
(12) Patent Application Publication
(10) Pub. No.: US 2014/0203259 A1
(43) Pub. Date: Jul. 24, 2014

(54) HOST FOR ORGANIC LIGHT EMITTING DEVICES

(71) Applicant: Universal Display Corporation, Ewing, NJ (US)

(72) Inventors: Aaron T. Fafarman, Philadelphia, PA (US); Xingchen Ye, Philadelphia, PA (US); Angang Dong, Ewing, NJ (US); Christopher B. Murray, Bala Cynwyd, PA (US); Cherie R. Kagan, Bala Cynwyd, PA (US); Chun Lin, Yardley, PA (US)

(73) Assignee: Universal Display Corporation, Ewing, NJ (US)

(21) Appl. No.: 14/158,301

(22) Filed: Jan. 17, 2014

Related U.S. Application Data
(60) Provisional application No. 61/754,283, filed on Jan. 18, 2013.

(51) Int. Cl. H01L 51/50; H01L 51/00

(52) U.S. Cl. CPC H01L 51/5024; H01L 51/0003
USPC 257/40; 438/46

(57) ABSTRACT

A first device comprising a first organic light emitting device (OLED) is described. The first OLED includes an anode, a cathode, and an emissive layer disposed between the anode and the cathode. The emissive layer includes a phosphorescent emissive dopant and a host material. The host material includes inorganic nanocrystals where (i) at least 50% of ligands bonded to said nanocrystals are compact ligands, (ii) an average interparticle distance between adjacent nanoparticles is ≦1 nm, or (iii) both. Also described are a method of making the emissive layer and a composition that includes the phosphorescent emissive dopant with the host materials that include the electronically-coupled inorganic nanocrystal host material.

### CROSS-REFERENCE TO RELATED APPLICATION

This application claims priority to U.S. Provisional Application No. 61/754,283, filed Jan. 18, 2013, the entire content of which is incorporated herein by reference.

### STATEMENT REGARDING JOINT RESEARCH AGREEMENT

The claimed invention was made by, on behalf of, and/or in connection with one or more of the following parties to a joint university corporation research agreement: University of Pennsylvania and the Universal Display Corporation. The agreement was in effect on and before the date the claimed invention was made, and the claimed invention was made as a result of activities undertaken within the scope of the agreement.

### FIELD OF THE INVENTION

The present invention relates to emissive layers for devices that include organic light emitting devices (OLED), particularly, emissive layers that include electronically-coupled inorganic nanocrystal host materials.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

Organic-inorganic hybrids are also being investigated to further enhance OLEDs. Hybrid materials incorporate desirable and tunable chemical and physical properties of the constituent organic and inorganic building blocks. Hybrids combine the low-cost, large-area processing and tunable and high photoluminescence yields notable of organic materials with the tunable optical properties, high carrier conductivities, and good photostability characteristic of inorganic nanostructures.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

One application for phosphorescent emissive molecules is a full color display. Industry standards for such a display call for pixels adapted to emit particular colors, referred to as “saturated” colors. In particular, these standards call for saturated red, green, and blue pixels. Color may be measured using CIE coordinates, which are well known to the art.

One example of a green emissive molecule is tris(2-phenylpyridine) iridium, denoted Ir(ppy)₃, which has the following structure:

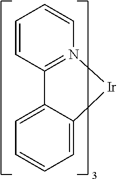

In this, and later figures herein, we depict the dative bond from nitrogen to metal (here, Ir) as a straight line.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

More details on OLEDs, and the definitions described above, can be found in U.S. Pat. No. 7,279,704, which is incorporated herein by reference in its entirety.

### SUMMARY OF THE INVENTION

A first device comprising a first organic light emitting device (OLED) is provided. The first OLED includes an anode, a cathode, and an emissive layer disposed between the anode and the cathode. The emissive layer includes a phosphorescent emissive dopant and a host material, that includes nanocrystals, wherein at least 50% of ligands bonded to the nanocrystals are compact ligands, thereby enhancing the electrical conductivity between adjacent nanocrystals.

Also provided is a first device comprising a first organic light emitting device (OLED), where the first OLED includes an anode, a cathode, and an emissive layer disposed between the anode and the cathode. The emissive layer includes a phosphorescent emissive dopant and a host material that includes nanocrystals, wherein an average interparticle distance between adjacent nanoparticles in the emissive layer is ≦1 nm, thereby enhancing the electrical conductivity between adjacent nanocrystals.

In another aspect, a method of making a first organic light emitting device is also provided. The method includes depositing a first electrode layer over a substrate; forming an emissive layer over the first electrode layer, the emissive layer comprising a phosphorescent emissive dopant and a nanocrystal host material; and depositing a second electrode layer over the emissive layer. The emissive layer is between the first electrode layer and the second electrode layer, and at least 50% of the ligands bonded to the nanocrystals are compact ligands. As used herein, “organic light emitting device” is intended to have its conventional meaning and also include devices that include inorganic materials—such as inorganic nanocrystals or other inorganic materials—as well.

### BRIEF DESCRIPTION OF THE DRAWINGS

The present disclosure is best understood from the following detailed description when read in conjunction with the accompanying drawing. It is emphasized that, according to common practice, the various features of the drawing are not necessarily to scale. On the contrary, the dimensions of the various features are arbitrarily expanded or reduced for clarity. Like numerals denote like features throughout the specification and drawings.

FIG. 1 shows an organic light emitting device.

FIG. 2 shows an inverted organic light emitting device that does not have a separate electron transport layer.

FIG. 3 shows a schematic of a process for making an emission layer according to some embodiments.

FIG. 4 shows a schematic of another process for making an emission layer according to some embodiments.

### DETAILED DESCRIPTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), which are incorporated by reference in their entireties. Phosphorescence is described in more detail in U.S. Pat. No. 7,279,704 at cols. 5-6, which are incorporated by reference.

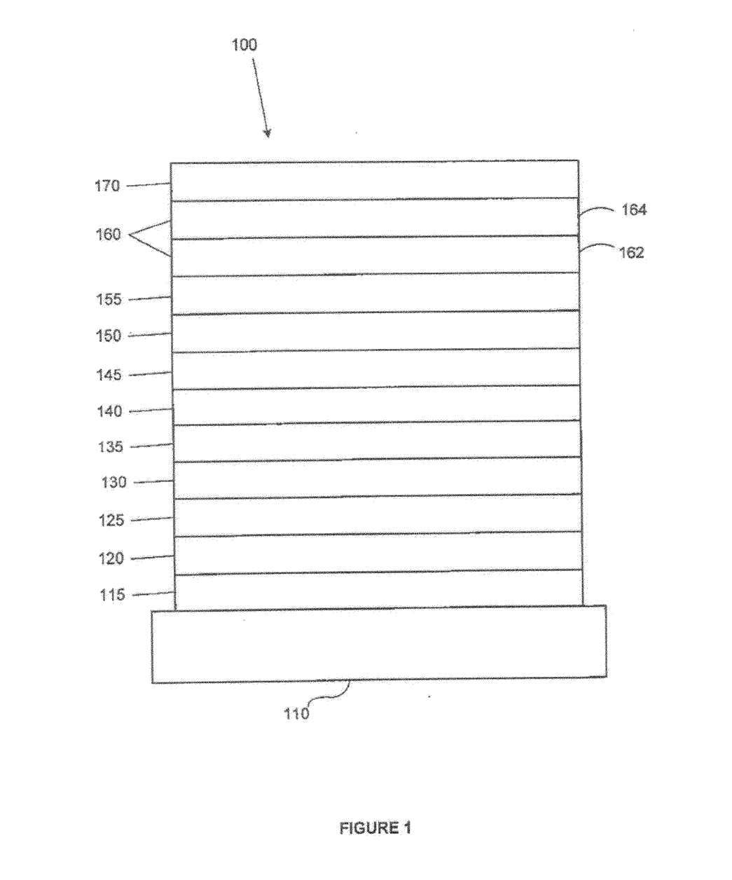

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

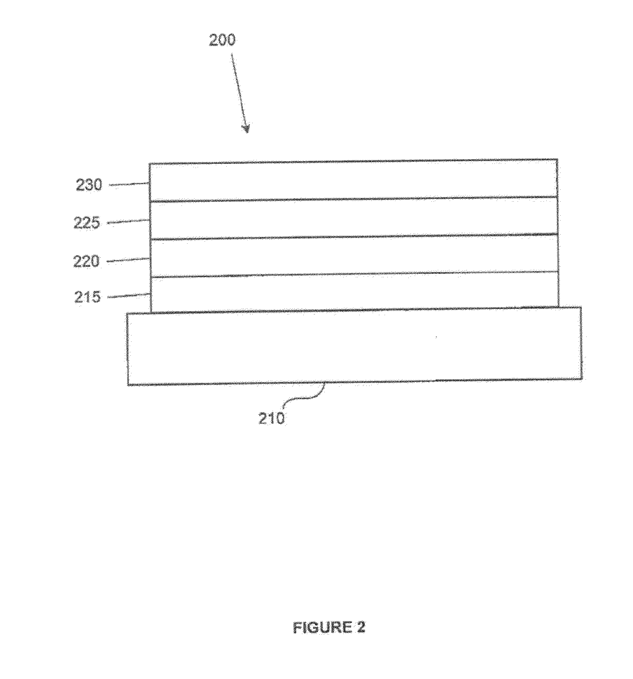

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

Devices fabricated in accordance with embodiments of the invention may be incorporated into a wide variety of consumer products, including flat panel displays, computer monitors, medical monitors, televisions, billboards, lights for interior or exterior illumination and/or signaling, heads up displays, fully transparent displays, flexible displays, laser printers, telephones, cell phones, personal digital assistants (PDAs), laptop computers, digital cameras, camcorders, viewfinders, micro-displays, vehicles, a large area wall, theater or stadium screen, or a sign. Various control mechanisms may be used to control devices fabricated in accordance with the present invention, including passive matrix and active matrix. Many of the devices are intended for use in a temperature range comfortable to humans, such as 18 degrees C. to 30 degrees C., and more preferably at room temperature (20-25 degrees C.).

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

The terms halo, halogen, alkyl, cycloalkyl, alkenyl, alkynyl, arylkyl, heterocyclic group, aryl, aromatic group, and heteroaryl are known to the art, and are defined in U.S. Pat. No. 7,279,704 at cols. 31-32, which are incorporated herein by reference.

A first device that includes a first OLED is described. The first device can be a consumer product. For example, the first device can be a lighting device such as a lighting panel incorporating the first OLED of the present disclosure.

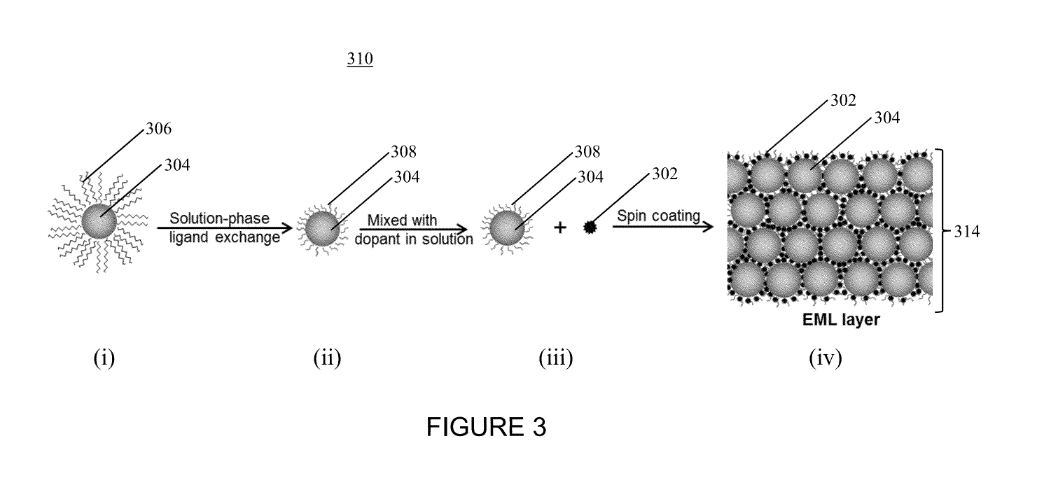

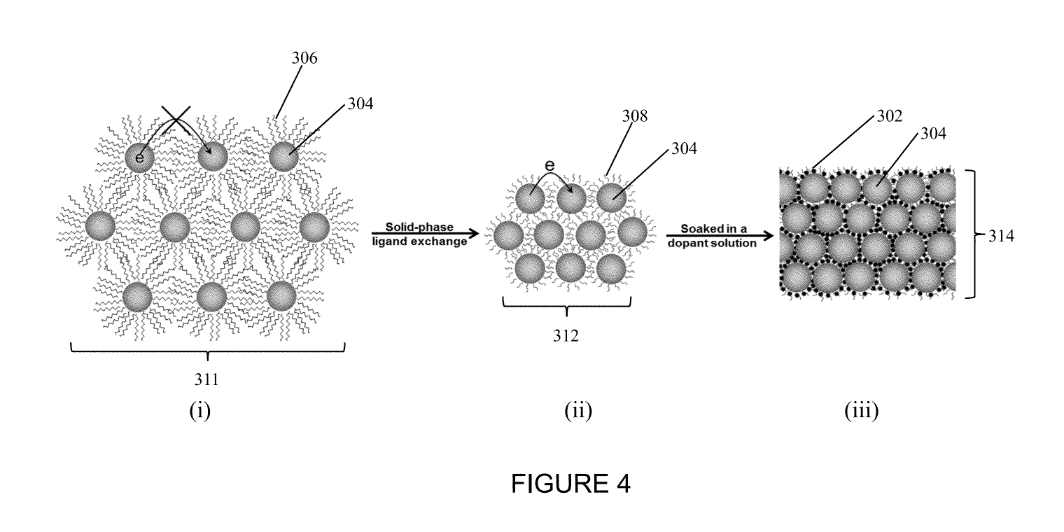

The first OLED can include an anode, a cathode, and an emissive layer disposed between the anode and the cathode. The emissive layer can include a phosphorescent emissive dopant and a host material that includes nanocrystals. Adjacent nanocrystals can be electronically-coupled. As shown in frame (iv) of FIG. 3 and frame (iii) of FIG. 4, the dopant 302 is distributed between nanocrystals 304.

The nanocrystals can include or be formed from an inorganic material. The inorganic material can include one or more inorganic materials selected from the group consisting of a sulfide, a selenide, a telluride, an arsenide, a phosphide, a nitride, a carbide, an oxide, a fluoride, an oxysulfide, and combinations thereof. More specifically, the inorganic material can include one or more inorganic materials selected from the group consisting of ZnO, In₂O₃, NiO, MnO, MoS₂, TiO₂, SiC, CdS, CdSe, GaAs, InP, ZnSe, ZnTe, GeS₂, InAs, CdTe, ZnS, CdSeₓS₁₋ₓ, ZnSeₓTe₁₋ₓ, AlₓZn₁₋ₓO, In₂₋ₓSnₓO₃, (Sn:In₂O₃), AlGaAs, CuInS₂, CuInSe₂, NaYF₄, BaTiO₃, SnO₂, SnO₂₋ₓFₓ, SnS₂, Gd₂O₂S, and combinations thereof.

The term “inorganic material,” as used herein refers to conventional inorganic compounds. Inorganic material can be different kinds of metals such as main group metal, transition metal, lanthanoid, or alloys. Inorganic material can contain groups 13 to 17 elements, such as oxides, sulfides, carbides; the most common ones are binary or ternary compounds; those with more than three elements can also be used; they can have metal elements, such as metal oxides, metal sulfides, metal carbides; or they can include other elements, such as silicon carbides and silicon oxides.

The inorganic nanocrystals can have a diameter ranging from 1-20 nm, or from 1-10 nm, or even from 1-5 nm. Nanocrystals formed using conventional wet chemical synthetic techniques, such as oleic acid ligand and high temperature TOPO techniques, produce nanocrystals with a surface covered with capping groups (e.g., long-chain organic ligands, such as fatty acids). The capping groups can be a layer of organic or inorganic ligands, these surface-passivating ligands are generally used to stabilize the nanocrystals in solvents and in the matrix. These nanocrystal structures can show quantum confinement effects that can be harnessed in creating complex heterostructures with electronic and optical properties that are tunable with the size, shape, and composition of the nanocrystals. The inorganic nanocrystal can have, for example, a CdSe core and a ZnS shell. Inorganic material as used herein does not encompass metal coordination complex, such as metal acetylacetonate.

While the native capping groups are helpful for purposes of stabilizing the nanocrystals in solvents and in the matrix, it has now been determined that they reduce conductivity between the nanocrystals. One of the features of the first device is the modification of the capping groups so that the inorganic nanocrystals are electronically-coupled. In some instances, the conductivity of a layer of inorganic nanocrystals can increase by at least two (2) orders of magnitude when the native long-chain organic ligands bonded to the nanocrystal are replaces with compact ligands.

In one embodiment, the average interparticle distance between adjacent nanoparticles in the emissive layer is ≦1 nm. The average interparticle distance between adjacent nanoparticles can be ≦0.5 nm, ≦0.4 nm or preferably even ≦0.3 nm. The average interparticle distance between adjacent nanoparticles can be measured by different modern techniques known to the persons skilled in the art, including, but not limited to, small-angle X-ray scattering, small-angle electron diffraction, or electron microscopy techniques.

In one embodiment, at least about 50% of ligands bonded to the nanocrystals are compact ligands. In some embodiments, the percentage of compact ligands bonded to the nanocrystals can be at least about 60%, at least about 70%, at least about 80%, at least about 90%, preferably at least about 95%, or at least about 99% of all ligands bonded to the nanocrystals. In some embodiments, the percentage of compact ligands bonded to the nanocrystals can be about 99.9% or less, about 99.5% or less, about 99% or less, about 95% or less, or about 90% or less.

As used herein, “long-chain organic ligands” refers to organic ligands that include a backbone of more than 6 carbon atoms. Examples of long-chain organic ligands include fatty acids and fatty acid esters (e.g., ethyl oleate) with backbone of more than 6 carbon atoms, such as oleic acid. As used herein, “short chain organic ligands” refers to organic ligands that include a backbone of 6 or fewer carbon atoms, while “compact ligands” refers to both inorganic ligands and short-chain organic ligands. Examples of compact ligands include ligands having fewer than 20 total atoms, or fewer than 10 total atoms.

The compact ligands can be short-chain organic ligands. The short-chain organic ligands can include at least one functional group selected from the group consisting of carboxylates, amines, thiols, phosphonates, and combinations thereof. The short-chain organic ligands can be selected from the group consisting of formic acid, 1,2-ethanedithiol, 1,4-benzene dithiol, ethylenediamine, and combinations thereof.

The compact ligands can be inorganic ligands. The inorganic ligands can be selected from the group consisting of chalcogenide complexes, simple chalcogenide ions, chalcogenocyanates, halides, tetrafluoroborate, hexafluorophosphate and combinations thereof.

As shown in frame (i) of FIG. 3, when inorganic nanocrystals 304 are formed using conventional solution-based techniques, they are coated with long-chain organic ligands 306. When, as shown in frame (ii) of FIG. 3, compact ligands 308 are substituted for the native long-chain organic ligands 306 on the surface of the inorganic nanoparticles 304, the compact ligands 308 allow improved conductivity between adjacent inorganic nanocrystals. While not necessary for practicing the invention, and not wishing to be bound by the theory, it is believed that the improved electrical coupling results because the substitution of compact ligands for long-chain organic ligands reduces the interparticle distance between adjacent nanoparticles.

The host material can have an energy band gap of less than 4 eV. The energy band gap of the host material can range from 1 to 4 eV or from 2 to 3 eV. The host material can have an energy band gap value larger than the triplet energy of the phosphorescent emissive dopant.

The concentration of the host material in the emissive layer can be 10 to 90 wt-%. Preferably, the concentration of the host material in the emissive layer can range from 10 to 70 wt-% or 10 to 80 wt-%.

The phosphorescent emissive dopant can include a transition metal complex. The phosphorescent emissive dopant can be an iridium complex, a platinum complex or a combination of both. The phosphorescent emissive dopant can be a transition metal complex having at least one ligand, or part of the ligand if the ligand is more than bidentate, selected from the group consisting of:

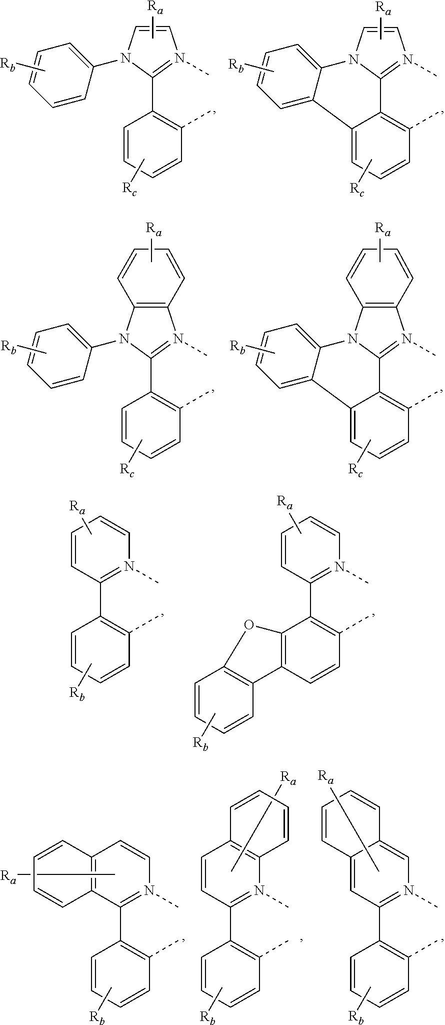

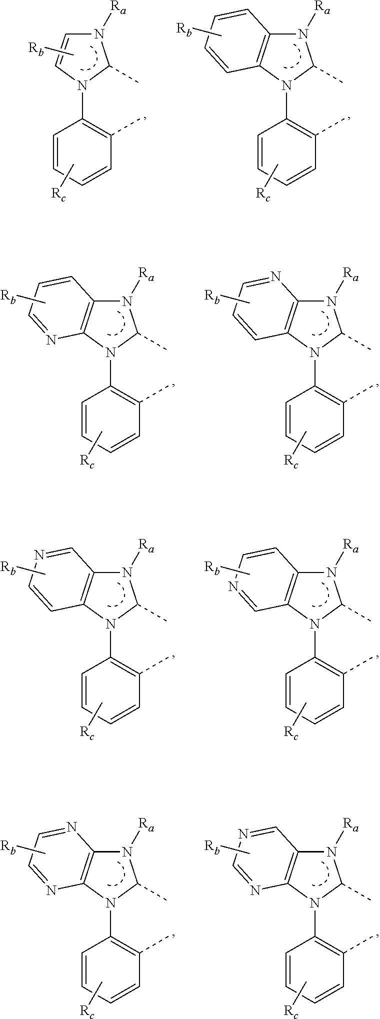

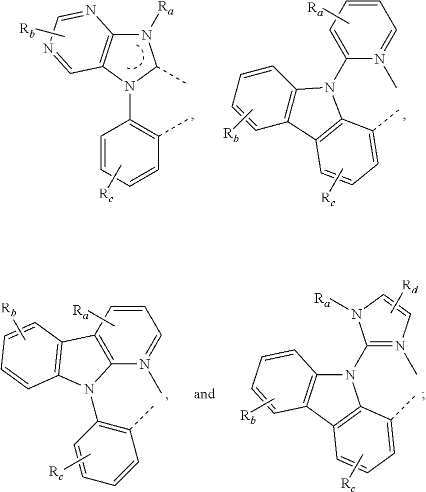

wherein Rₐ, R_{b}, R_{c}, and R_{d} may represent mono, di, tri, or tetra substitution, or no substitution; and

wherein Rₐ, R_{b}, R_{c}, and R_{d} are independently selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, bridge ligands, and combinations thereof; and wherein two adjacent substituents of Rₐ, R_{b}, R_{c}, and R_{d} are optionally joined to form a fused ring or form a multidentate ligand.

The emissive layer can include a second host material, a second phosphorescent emissive dopant, or both. In such embodiments, the host material and the second host material can be different, the phosphorescent emissive dopant and the second phosphorescent dopant can be different, or both. The concentration of the second host material in the emissive layer can be at least 10 wt-%. The second host material can be present in the emissive layer in an amount ranging from 10 to 85 wt-% or from 10 to 50 wt-%. When a second host material, or “cohost,” is present in the emissive layer, the concentration of the inorganic nanocrystal host can range from 10 to 50 wt-%.

The host material can consist essentially of a substance containing at least 70 wt-% inorganic material. In some embodiments, the host material can consist essentially of a substance containing at least 80 wt-% inorganic material, or at least 90 wt-% inorganic material, or at least 95 wt-% inorganic material. In other embodiments, the host material can consist essentially of organic material.

The second host material in the emissive layer can include an organic compound selected from the group consisting of triphenylene, dibenzothiophene, aza-dibenzothiophene, dibenzofuran, aza-dibenzofuran, carbazole, aza-carbazole, and combinations thereof. The second host material can include at least one compound selected from the group consisting of:

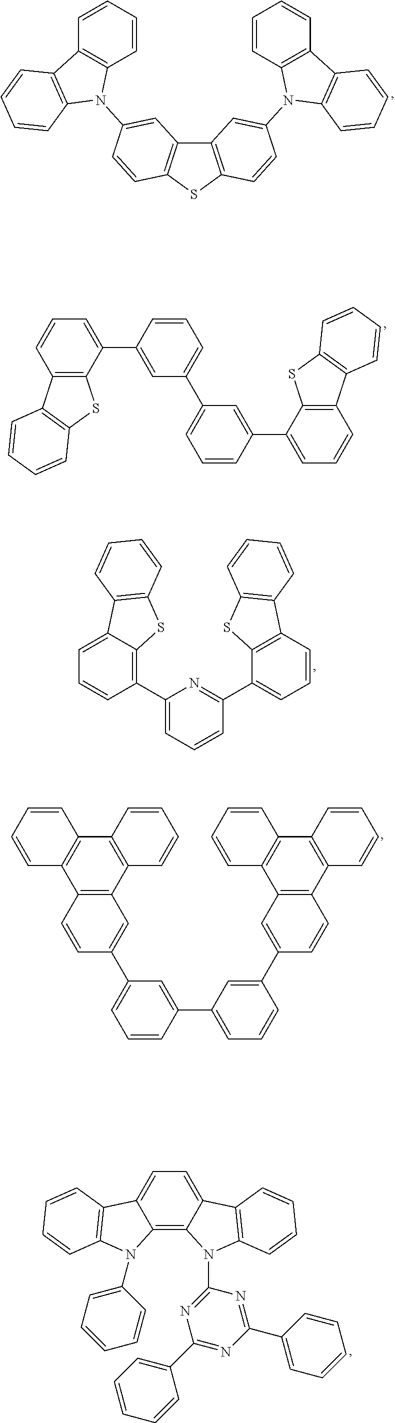

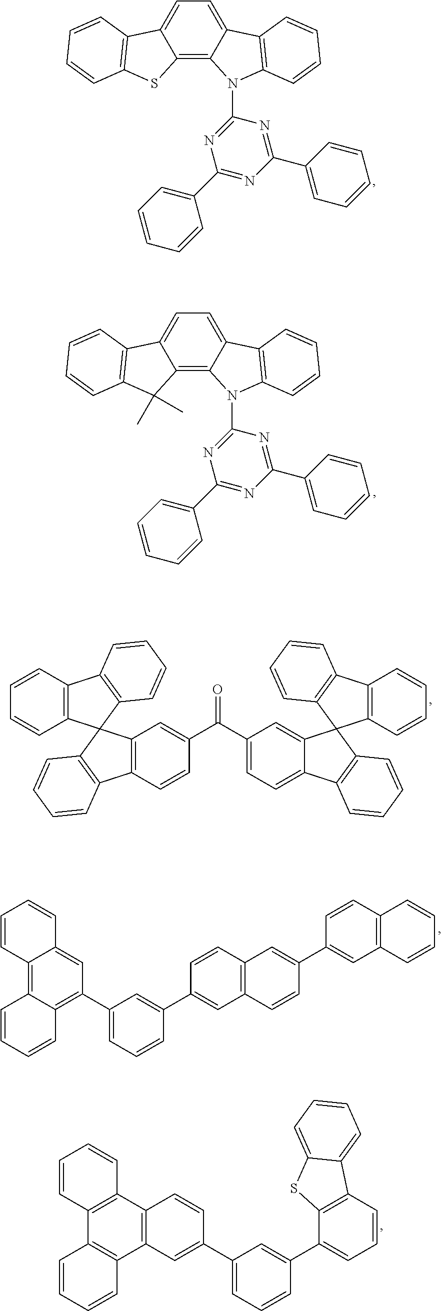

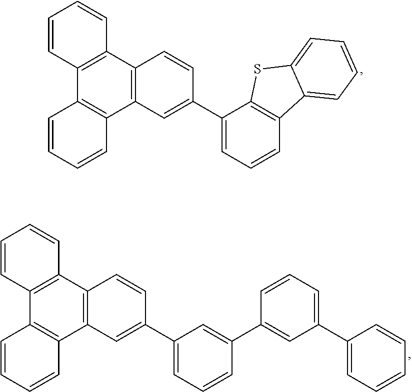

and combinations thereof.

According to another aspect of the present disclosure, a composition that includes a phosphorescent emissive dopant and a host material is also described. The host material includes nanocrystals modified to replace some or all of the native long-chain organic ligands with short chain ligands. This composition can include any of the host materials and phosphorescent emissive dopants described herein in any combination.

The composition can be provided as a solution with the host(s) and phosphorescent emissive dopant(s) dispersed in a solvent. Such a solution can be used to spin coat a film layer that includes the host material and the phosphorescent emissive dopant.

The solvent can be a polar solvent. As used herein, a polar solvent is a solvent in whose molecules there is a significant dipole moment. Polar solvents typically have dielectric values much greater than 2. Examples of polar solvents include, but are not limited to, dimethylformamide, formamide, acetonitrile, methanol, ethanol, isopropanol, pyridine and acetone. Examples of polar solvents with lower dielectric values include, but are not limited to, hexane, toluene, tetrahydrofuran, dichlorobenzene.

Alternately, the composition can be a film layer that includes both phosphorescent emissive dopant(s) and nanocrystal(s), having the native long-chain organic ligands partially or completely substituted by compact ligands. The composition can be deposited over an anode, a cathode, or another substrate. The composition can be deposited between an anode and a cathode.

A method of making a first organic light emitting device is also described. The method can include depositing a first electrode layer over a substrate; forming an emissive layer that includes a phosphorescent emissive dopant and a nanocrystal host material; and depositing a second electrode layer. The emissive layer can be between the first electrode layer and the second electrode layer.

When the first OLED has an architecture as the example shown in FIG. 1, the first electrode is an anode and the second electrode is a cathode. In an inverted OLED architecture such as the example shown in FIG. 2, the first electrode is a cathode and the second electrode is an anode.

In some embodiments, at least 50% of the ligands bonded to the nanocrystals can be compact ligands, the average interparticle distance between adjacent nanoparticles in the emissive layer is ≦1 nm, or both. The emissive layer can include any of the host materials and phosphorescent emissive dopants described herein in any combination.

The anode layer can be deposited over a substrate, over the emissive layer, or both. The cathode layer can be deposited over the emissive layer, over a substrate, or both. The emissive layer can be formed over the anode layer or over the cathode layer.

The step of forming the emissive layer can include replacing long-chain organic ligands 306 bonded to the nanocrystal host 304 with compact ligands 308 to form a modified nanocrystal host material 310 in which at least 50% of the ligands bonded to the nanocrystals 304 are compact ligands 308. Examples of modified nanocrystal hosts 310 are shown in frame (ii) of FIG. 3 and frame (ii) of FIG. 4.

The replacement step can be accomplished by a solution-phase ligand-exchange process, such as that of FIG. 3. In such embodiments, the emissive layer can be formed by dispersing the modified nanocrystal host material 310 in a polar solvent, and depositing a layer of the modified nanocrystal host material over a substrate (e.g., an anode or cathode) by solution deposition processing. The depositing step can include depositing both the modified nanocrystal host and the phosphorescent emissive dopant simultaneously to form an emissive layer 314, as shown in frame (iii) of FIG. 3. As shown in FIG. 3, the solution deposition process can be a spin coating process. Alternately, similar to frames (ii) and (iii) of FIG. 4, the modified nanocrystal host 310 can be deposited first to form a modified nanocrystal host layer 312. The emissive layer 314 can then be formed by diffusing the phosphorescent emissive dopant 302 into the modified nanocrystal host layer 312 by immersing the modified nanocrystal host material layer 312 in a solution containing the phosphorescent emissive dopant.

While not the only solution-phase ligand-exchange technique that may be useful for this method of forming the emissive layer, the following describes an example of a solution-phase ligand exchange process that may be useful. To a hexane solution containing inorganic nanocrystals capped with oleic acid, an appropriate amount of dimethylformamide (or other polar solvent) solution containing compact ligands is added (in general, an excess amount of short ligands are added to ensure complete replacement of oleic acid). The addition of the compact ligand solution leads to a phase separation (normally, nanocrystal hexane solution is the top phase, while a compact ligand dimethylformamide solution is the bottom phase). The solution mixture is then stirred vigorously on a stir plate to promote ligand exchange, which is manifested by the phase transfer of nanocrystals from the hexane phase to the dimethylformamide phase. After ligand exchange, the compact-ligand-capped nanocrystals are purified by addition of pure solvent followed by centrifugation and then re-dispersed in dimethylformamide (or other polar solvent) to form a stable or meta-stable solution. To form the emissive layer, an appropriate amount of emissive dopant molecules are added into the nanocrystal dimethylformamide solution and the ratio between nanocrystal host and dopant molecules can be adjusted by changing the amount of dopant molecules added. The emissive layer is then formed by spin-coating the solution of nanocrystal and dopant on a substrate, with the layer thickness tunable by adjusting nanocrystal-dopant concentration as well as spin speed.

The replacement step can also be accomplished by a solid-phase ligand-exchange process. As shown in FIG. 4, the emissive layer can be formed by depositing a solid film of the nanocrystal host material over a substrate (e.g., an anode or cathode layer) to form a native nanocrystal host layer 311; immersing the solid film 311 in a solution containing compact ligands 308, thereby replacing any long-chain organic ligands 306 coupled to the nanocrystal host material 304 with compact ligands 308 to form a modified nanocrystal layer 312; and diffusing the phosphorescent emissive dopant 302 into the modified nanocrystal host material 310 by immersing the modified nanocrystal host material layer 312 in a solution containing the phosphorescent emissive dopant 302. Alternately, the emissive layer (step (i) in FIG. 4) can be co-depositing the phosphorescent emissive dopant 302 and the nanocrystal host material 304, which eliminates step (iii) of FIG. 4. In this alternate embodiment, it may be beneficial to use solvents, such as acetone or methanol, that will not dissolve the dopant during the immersing-replacing steps.

While not the only solid-phase ligand-exchange technique that may be useful for this method of forming the emissive layer, the following describes an example of a solid-phase ligand exchange process that may be useful. A nanocrystal host film is formed by spin coating nanocrystal solution in toluene on a substrate. The layer thickness is tunable by varying the nanocrystal concentration as well as spin speed. The nanocrystal film is then immersed into an acetonitrile solution containing compact ligands for ligand exchange. The replacement of the native long-chain organic ligands (e.g., oleic acid) ligands by compact ligands leads to an electronically-coupled nanocrystal film. The emissive layer is then formed by immersing the nanocrystal film in an acetonitrile solution containing emissive dopant molecules, which diffuse into the interstitial voids between adjacent nanocrystals. The nanocrystal host/dopant ratio can be adjusted by varying the dopant concentration.

Combination with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

### HIL/HTL:

A hole injecting/transporting material to be used in the present invention is not particularly limited, and any compound may be used as long as the compound is typically used as a hole injecting/transporting material. Examples of the material include, but not limit to: a phthalocyanine or porphryin derivative; an aromatic amine derivative; an indolocarbazole derivative; a polymer containing fluorohydrocarbon; a polymer with conductivity dopants; a conducting polymer, such as PEDOT/PSS; a self-assembly monomer derived from compounds such as phosphonic acid and sliane derivatives; a metal oxide derivative, such as MoOₓ; a p-type semiconducting organic compound, such as 1,4,5,8,9,12-Hexaazatriphenylenehexacarbonitrile; a metal complex, and a cross-linkable compounds.

Examples of aromatic amine derivatives used in HIL or HTL include, but not limit to the following general structures:

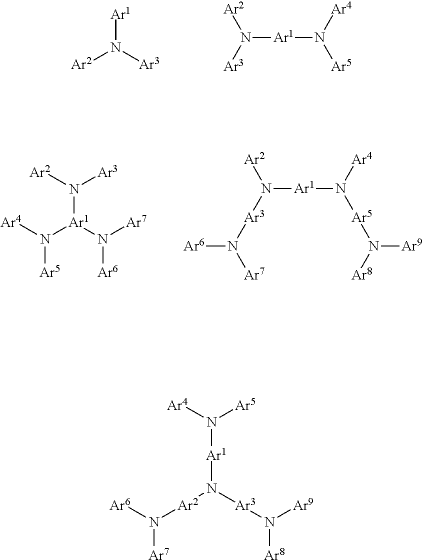

Each of Ar¹ to Ar⁹ is selected from the group consisting aromatic hydrocarbon cyclic compounds such as benzene, biphenyl, triphenyl, triphenylene, naphthalene, anthracene, phenalene, phenanthrene, fluorene, pyrene, chrysene, perylene, azulene; group consisting aromatic heterocyclic compounds such as dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine; and group consisting 2 to 10 cyclic structural units which are groups of the same type or different types selected from the aromatic hydrocarbon cyclic group and the aromatic heterocyclic group and are bonded to each other directly or via at least one of oxygen atom, nitrogen atom, sulfur atom, silicon atom, phosphorus atom, boron atom, chain structural unit and the aliphatic cyclic group. Wherein each Ar is further substituted by a substituent selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof.

In one aspect, Ar¹ to Ar⁹ is independently selected from the group consisting of:

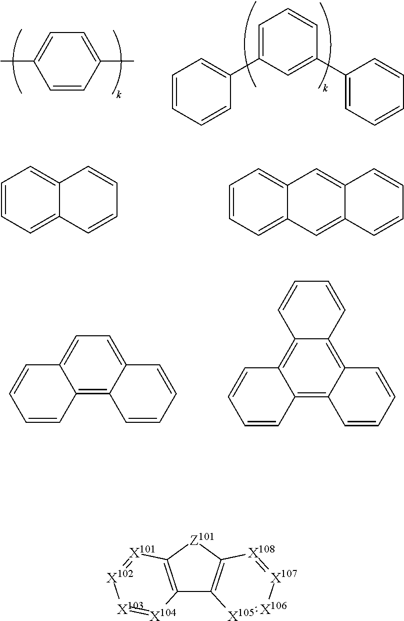

k is an integer from 1 to 20; X¹⁰¹ to X¹⁰⁸ is 1 (including CH) or N; Z¹⁰¹ is NAr¹, O, or S; Ar¹ has the same group defined above.

Examples of metal complexes used in HIL or HTL include, but not limit to the following general formula:

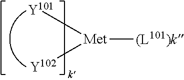

Met is a metal, which can have an atomic weight greater than 40; (Y¹⁰¹-Y¹⁰²) is a bidentate ligand, Y¹⁰¹ and Y¹⁰² are independently selected from C, N, O, P, and S; L¹⁰¹ is an ancillary ligand; k′ is an integer value from 1 to the maximum number of ligands that may be attached to the metal; and k′+k″ is the maximum number of ligands that may be attached to the metal.

In one aspect, (Y¹⁰¹-Y¹⁰²) is a 2-phenylpyridine derivative.

In another aspect, (Y¹⁰¹-Y¹⁰²) is a carbene ligand.

In another aspect, Met is selected from Ir, Pt, Os, and Zn.

In a further aspect, the metal complex has a smallest oxidation potential in solution vs. Fc⁺/Fc couple less than about 0.6 V.

### Host:

The light emitting layer of the organic EL device of the present invention preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. While the Table below categorizes host materials as preferred for devices that emit various colors, any host material may be used with any dopant so long as the triplet criteria is satisfied.

Examples of metal complexes used as host are preferred to have the following general formula:

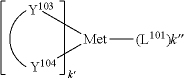

Met is a metal; (Y¹⁰³-Y¹⁰⁴) is a bidentate ligand, Y¹⁰³ and Y¹⁰⁴ are independently selected from C, N, O, P, and S; L¹⁰¹ is an another ligand; k′ is an integer value from 1 to the maximum number of ligands that may be attached to the metal; and k′+k″ is the maximum number of ligands that may be attached to the metal.

In one aspect, the metal complexes are:

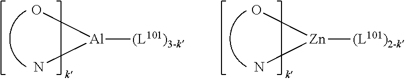

(O—N) is a bidentate ligand, having metal coordinated to atoms O and N.

In another aspect, Met is selected from Ir and Pt.

In a further aspect, (Y¹⁰³-Y¹⁰⁴) is a carbene ligand.

Examples of organic compounds used as host are selected from the group consisting aromatic hydrocarbon cyclic compounds such as benzene, biphenyl, triphenyl, triphenylene, naphthalene, anthracene, phenalene, phenanthrene, fluorene, pyrene, chrysene, perylene, azulene; group consisting aromatic heterocyclic compounds such as dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine; and group consisting 2 to 10 cyclic structural units which are groups of the same type or different types selected from the aromatic hydrocarbon cyclic group and the aromatic heterocyclic group and are bonded to each other directly or via at least one of oxygen atom, nitrogen atome, sulfur atom, silicon atom, phosphorus atom, boron atom, chain structural unit and the aliphatic cyclic group. Wherein each group is further substituted by a substituent selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof.

In one aspect, host compound contains at least one of the following groups in the molecule:

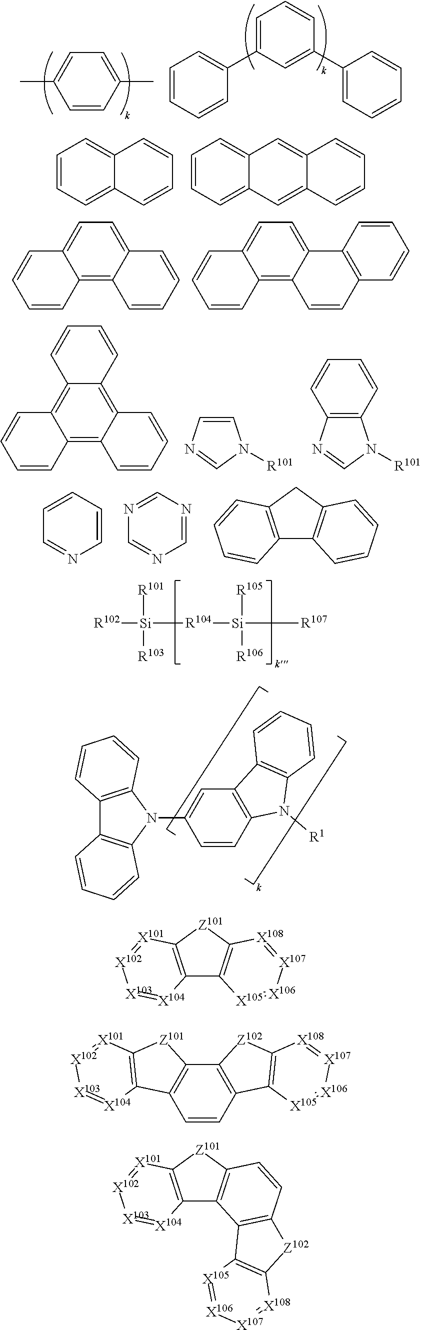

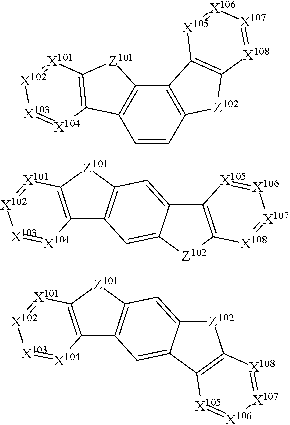

R¹⁰¹ to R¹⁰⁷ is independently selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, when it is aryl or heteroaryl, it has the similar definition as Ar's mentioned above.

k is an integer from 0 to 20 or 1 to 20; k′″ is an integer from 0 to 20.

X¹⁰¹ to X¹⁰⁸ is selected from C (including CH) or N.

Z¹⁰¹ and Z¹⁰² is selected from NR¹⁰¹, O, or S.

### HBL:

A hole blocking layer (HBL) may be used to reduce the number of holes and/or excitons that leave the emissive layer. The presence of such a blocking layer in a device may result in substantially higher efficiencies as compared to a similar device lacking a blocking layer. Also, a blocking layer may be used to confine emission to a desired region of an OLED.

In one aspect, compound used in HBL contains the same molecule or the same functional groups used as host described above.

In another aspect, compound used in HBL contains at least one of the following groups in the molecule:

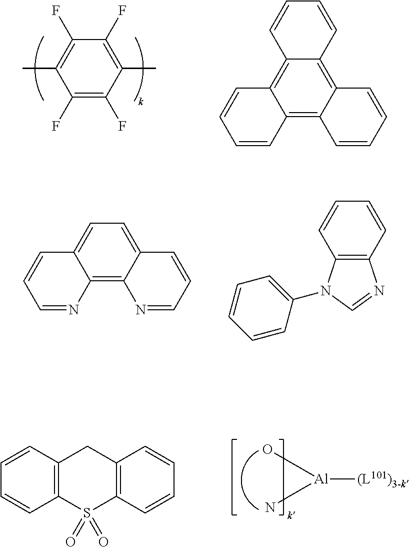

k is an integer from 1 to 20; L¹⁰¹ is an another ligand, k′ is an integer from 1 to 3.

### ETL:

Electron transport layer (ETL) may include a material capable of transporting electrons. Electron transport layer may be intrinsic (undoped), or doped. Doping may be used to enhance conductivity. Examples of the ETL material are not particularly limited, and any metal complexes or organic compounds may be used as long as they are typically used to transport electrons.

In one aspect, compound used in ETL contains at least one of the following groups in the molecule:

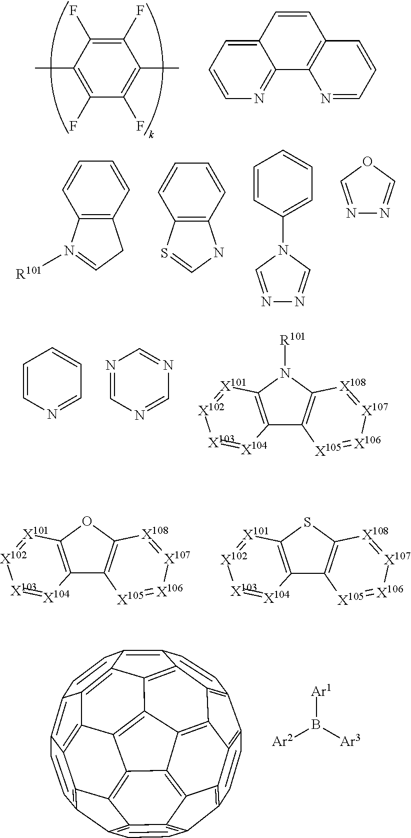

R¹⁰¹ is selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof, when it is aryl or heteroaryl, it has the similar definition as Ar's mentioned above.

Ar¹ to Ar³ has the similar definition as Ar's mentioned above.

k is an integer from 1 to 20.

X¹⁰¹ to X¹⁰⁸ is selected from C (including CH) or N.

In another aspect, the metal complexes used in ETL contains, but not limit to the following general formula:

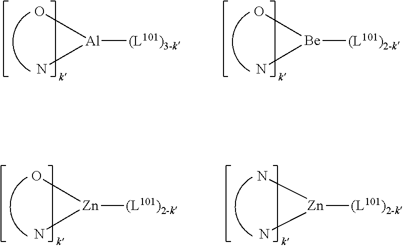

(O—N) or (N—N) is a bidentate ligand, having metal coordinated to atoms O, N or N, N; L¹⁰¹ is another ligand; k′ is an integer value from 1 to the maximum number of ligands that may be attached to the metal.

In any above-mentioned compounds used in each layer of the OLED device, the hydrogen atoms can be partially or fully deuterated. Thus, any specifically listed substituent, such as, without limitation, methyl, phenyl, pyridyl, etc. encompasses undeuterated, partially deuterated, and fully deuterated versions thereof. Similarly, classes of substituents such as, without limitation, alkyl, aryl, cycloalkyl, heteroaryl, etc. also encompass undeuterated, partially deuterated, and fully deuterated versions thereof.

In addition to and/or in combination with the materials disclosed herein, many hole injection materials, hole transporting materials, host materials, dopant materials, exiton/hole blocking layer materials, electron transporting and electron injecting materials may be used in an OLED. Non-limiting examples of the materials that may be used in an OLED in combination with materials disclosed herein are listed in Table 1 below. Table 1 lists non-limiting classes of materials, non-limiting examples of compounds for each class, and references that disclose the materials.

TABLE 1

| | | |
|---|---|---|
| MATERIAL | EXAMPLES OF MATERIAL | PUBLICATIONS |

Hole injection materials

| | | |
|---|---|---|
| Phthalocyanine and porphryin compounds | 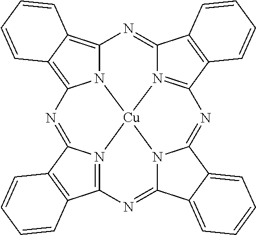 | Appl. Phys. Lett. 69, 2160 (1996) |
| Starburst triarylamines | 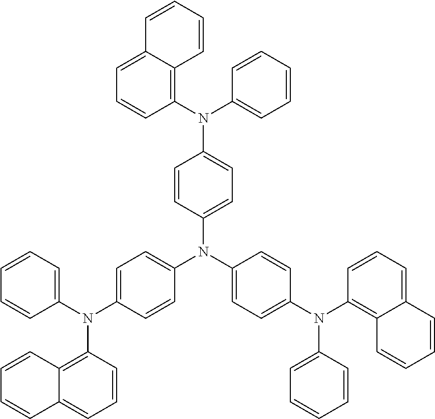 [SMILES: c1ccc(N(c2ccc(N(c3ccc(N(c4ccccc4)c4cccc5ccccc45)cc3)c3ccc(N(c4ccccc4)c4cccc5ccccc45)cc3)cc2)c2cccc3ccccc23)cc1] | J. Lumin. 72-74, 985 (1997) |
| CFₓ Fluorohydrocarbon polymer | 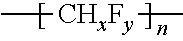 | Appl. Phys. Lett. 78, 673 (2001) |
| Conducting polymers (e.g., PEDOT:PSS, polyaniline, polypthiophene) | 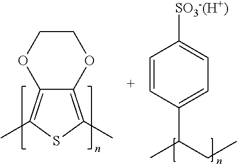 | Synth. Met. 87, 171 (1997) WO2007002683 |
| Phosphonic acid and sliane SAMs | 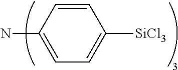 | US20030162053 |
| Triarylamine or polythiophene polymers with conductivity dopants | 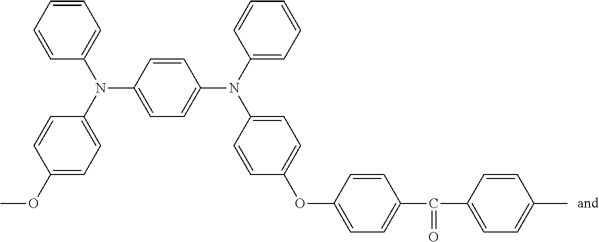 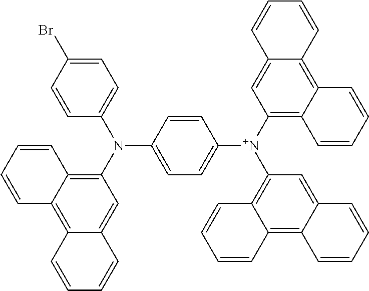 [SMILES: Brc1ccc(N(c2ccc([NH+](c3cc4ccccc4c4ccccc34)c3cc4ccccc4c4ccccc34)cc2)c2cc3ccccc3c3ccccc23)cc1] 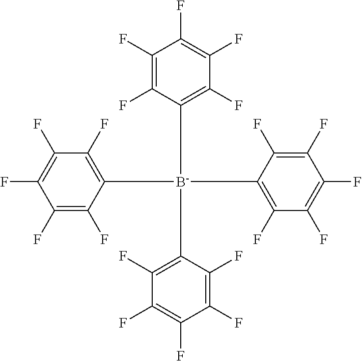 [SMILES: Fc1c(F)c(F)c([B-](c2c(F)c(F)c(F)c(F)c2F)(c2c(F)c(F)c(F)c(F)c2F)c2c(F)c(F)c(F)c(F)c2F)c(F)c1F] | EP1725079A1 |
| Organic compounds with conductive inorganic compounds, such as molybdenum and tungsten oxides | 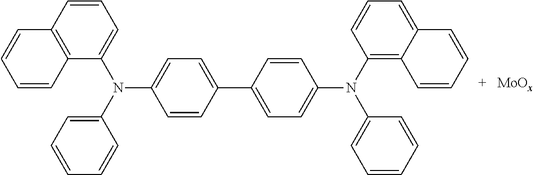 [SMILES: c1ccc(N(c2ccc(-c3ccc(N(c4ccccc4)c4cccc5ccccc45)cc3)cc2)c2cccc3ccccc23)cc1] | US20050123751 SID Symposium Digest, 37, 923 (2006) WO2009018009 |
| n-type semiconducting organic complexes | 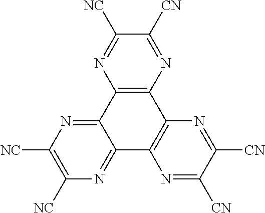 [SMILES: N#Cc1nc2c3nc(C#N)c(C#N)nc3c3nc(C#N)c(C#N)nc3c2nc1C#N] | US20020158242 |
| Metal organometallic complexes | 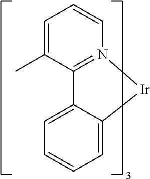 | US20060240279 |
| Cross-linkable compounds | 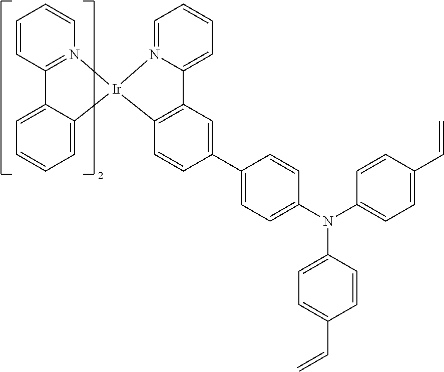 | US20080220265 |
| Polythiophene based polymers and copolymers | 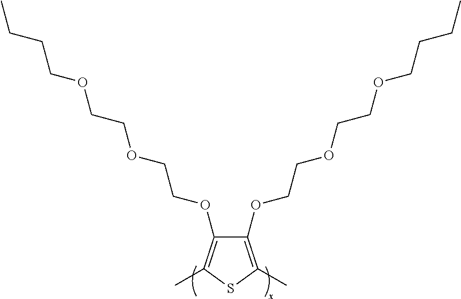 | WO2011075644 EP2350216 |

Hole transporting materials

| | | |
|---|---|---|
| Triarylamines (e.g., TPD, α-NPD) | 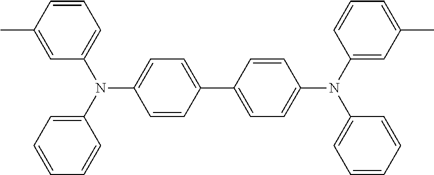 | Appl. Phys. Lett. 51, 913 (1987) |
| | 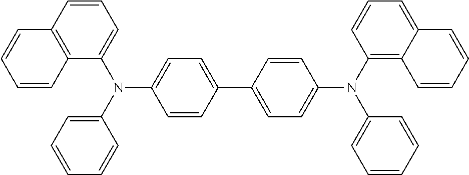 [SMILES: c1ccc(N(c2ccc(-c3ccc(N(c4ccccc4)c4cccc5ccccc45)cc3)cc2)c2cccc3ccccc23)cc1] | US5061569 |
| | 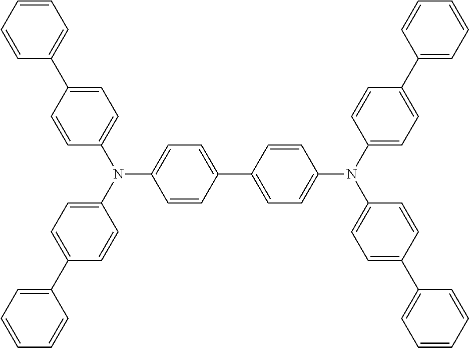 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1] | EP650955 |
| | 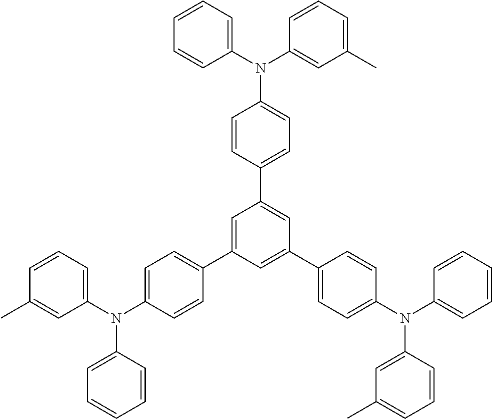 [SMILES: Cc1cccc(N(c2ccccc2)c2ccc(-c3cc(-c4ccc(N(c5ccccc5)c5cccc(C)c5)cc4)cc(-c4ccc(N(c5ccccc5)c5cccc(C)c5)cc4)c3)cc2)c1] | J. Mater. Chem. 3, 319 (1993) |
| | 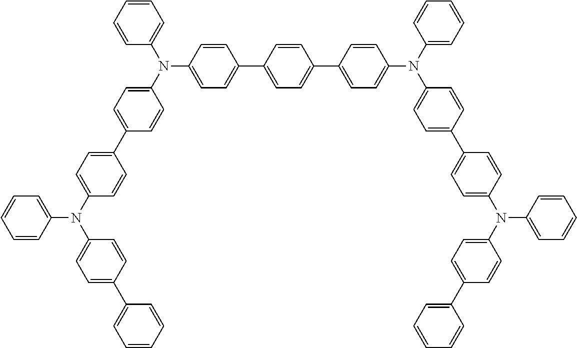 [SMILES: c1ccc(-c2ccc(N(c3ccccc3)c3ccc(-c4ccc(N(c5ccccc5)c5ccc(-c6ccc(-c7ccc(N(c8ccccc8)c8ccc(-c9ccc(N(c%10ccccc%10)c%10ccc(-c%11ccccc%11)cc%10)cc9)cc8)cc7)cc6)cc5)cc4)cc3)cc2)cc1] | Appl. Phys. Lett. 90, 183503 (2007) |
| | 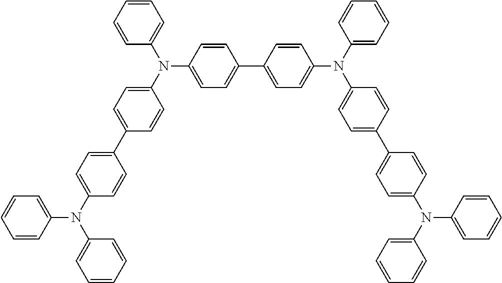 [SMILES: c1ccc(N(c2ccccc2)c2ccc(-c3ccc(N(c4ccccc4)c4ccc(-c5ccc(N(c6ccccc6)c6ccc(-c7ccc(N(c8ccccc8)c8ccccc8)cc7)cc6)cc5)cc4)cc3)cc2)cc1] | Appl. Phys. Lett. 90, 183503 (2007) |
| Triaylamine on spirofluorene core | 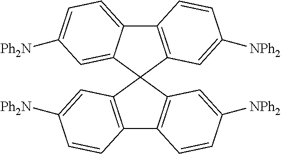 | Synth. Met. 91, 209 (1997) |
| Arylamine carbazole compounds | 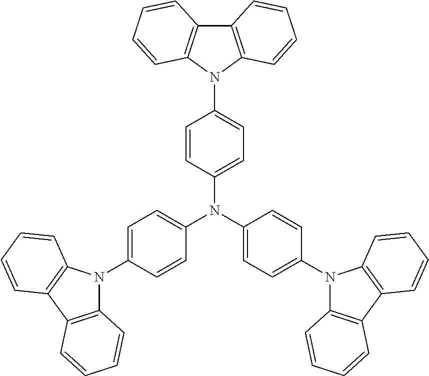 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1] | Adv. Mater. 6, 677 (1994), US20080124572 |
| Triarylamine with (di)benzothiophene/ (di)benzofuran | 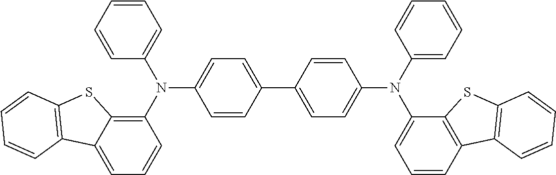 [SMILES: c1ccc(N(c2ccc(-c3ccc(N(c4ccccc4)c4cccc5c4sc4ccccc45)cc3)cc2)c2cccc3c2sc2ccccc23)cc1] | US20070278938, US20080106190 US20110163302 |
| Indolocarbazoles | 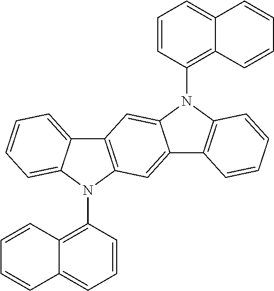 [SMILES: c1ccc2c(-n3c4ccccc4c4cc5c(cc43)c3ccccc3n5-c3cccc4ccccc34)cccc2c1] | Synth. Met. 111, 421 (2000) |
| Isoindole compounds | 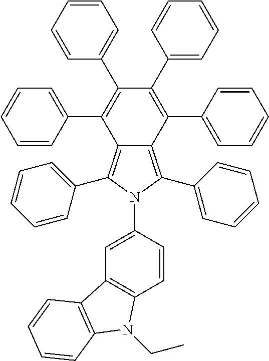 [SMILES: CCn1c2ccccc2c2cc(-n3c(-c4ccccc4)c4c(-c5ccccc5)c(-c5ccccc5)c(-c5ccccc5)c(-c5ccccc5)c4c3-c3ccccc3)ccc21] | Chem. Mater. 15, 3148 (2003) |
| Metal carbene complexes | 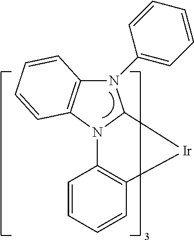 | US20080018221 |

Phosphorescent OLED host materials
Red hosts

| | | |
|---|---|---|
| Arylcarbazoles | 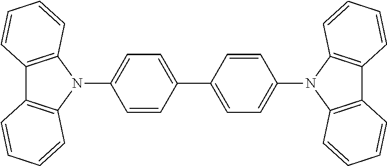 [SMILES: c1ccc2c(c1)c1ccccc1n2-c1ccc(-c2ccc(-n3c4ccccc4c4ccccc43)cc2)cc1] | Appl. Phys. Lett. 78, 1622 (2001) |
| Metal 8- hydroxyquinolates (e.g., Alq₃, BAlq) | 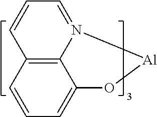 | Nature 395, 151 (1998) |
| | 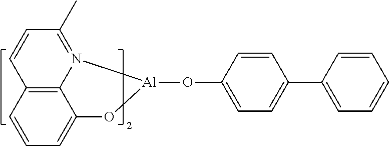 | US20060202194 |
| | 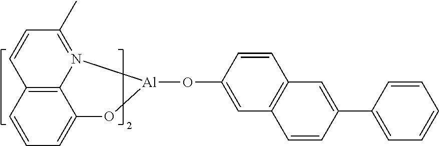 | WO2005014551 |
| | 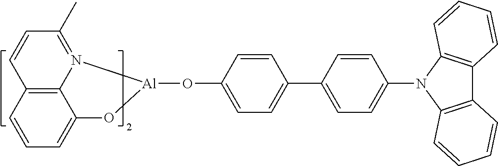 | WO2006072002 |
| Metal phenoxybenzothiazole compounds | 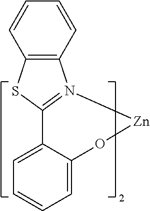 | Appl. Phys. Lett. 90, 123509 (2007) |
| Conjugated oligomers and polymers (e.g., polyfluorene) | 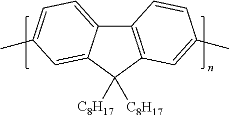 | Org. Electron. 1, 15 (2000) |
| Aromatic fused rings | 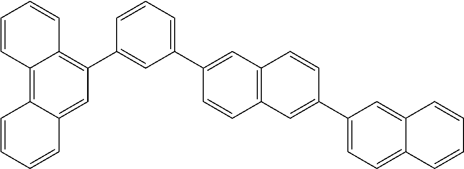 [SMILES: c1cc(-c2ccc3cc(-c4ccc5ccccc5c4)ccc3c2)cc(-c2cc3ccccc3c3ccccc23)c1] | WO2009066779, WO2009066778, WO2009063833, US20090045731, US20090045730, WO2009008311, US20090008605, US20090009065 |
| Zinc complexes | 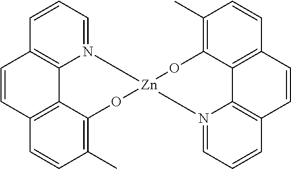 | WO2010056066 |
| Chrysene based compounds | 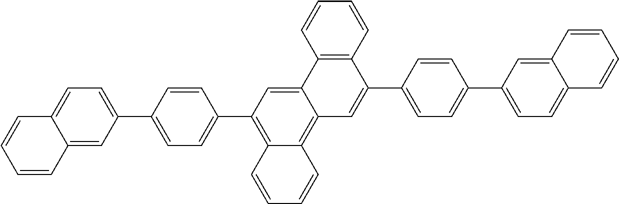 [SMILES: c1ccc2cc(-c3ccc(-c4cc5c6ccccc6c(-c6ccc(-c7ccc8ccccc8c7)cc6)cc5c5ccccc45)cc3)ccc2c1] | WO2011086863 |

Green hosts

| | | |
|---|---|---|
| Arylcarbazoles | 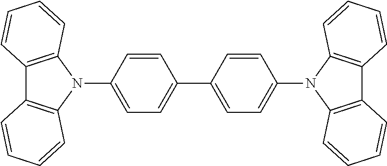 [SMILES: c1ccc2c(c1)c1ccccc1n2-c1ccc(-c2ccc(-n3c4ccccc4c4ccccc43)cc2)cc1] | Appl. Phys. Lett. 78, 1622 (2001) |
| | 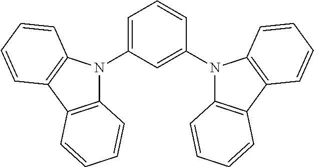 [SMILES: c1cc(-n2c3ccccc3c3ccccc32)cc(-n2c3ccccc3c3ccccc32)c1] | US20030175553 |
| | 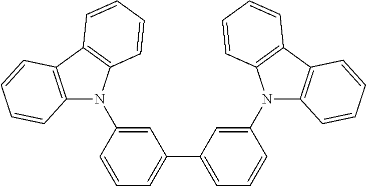 [SMILES: c1cc(-c2cccc(-n3c4ccccc4c4ccccc43)c2)cc(-n2c3ccccc3c3ccccc32)c1] | WO2001039234 |
| Aryltriphenylene compounds | 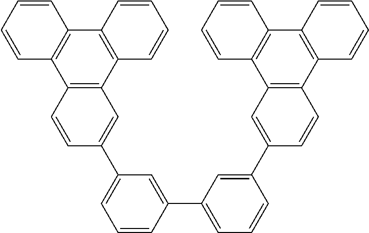 [SMILES: c1cc(-c2cccc(-c3ccc4c5ccccc5c5ccccc5c4c3)c2)cc(-c2ccc3c4ccccc4c4ccccc4c3c2)c1] | US20060280965 |
| | 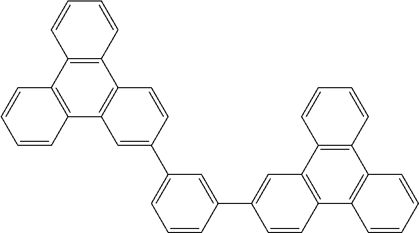 [SMILES: c1cc(-c2ccc3c4ccccc4c4ccccc4c3c2)cc(-c2ccc3c4ccccc4c4ccccc4c3c2)c1] | US20060280965 |
| | 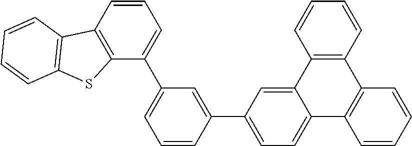 [SMILES: c1cc(-c2ccc3c4ccccc4c4ccccc4c3c2)cc(-c2cccc3c2sc2ccccc23)c1] | WO2009021126 |
| Poly-fused heteroaryl compounds | 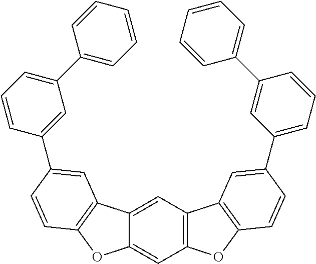 [SMILES: c1ccc(-c2cccc(-c3ccc4oc5cc6oc7ccc(-c8cccc(-c9ccccc9)c8)cc7c6cc5c4c3)c2)cc1] | US20090309488 US20090302743 US20100012931 |
| Donor acceptor type molecules | 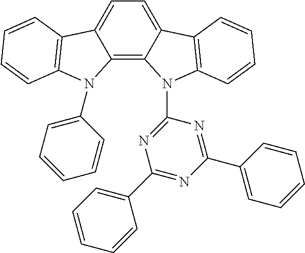 [SMILES: c1ccc(-c2nc(-c3ccccc3)nc(-n3c4ccccc4c4ccc5c6ccccc6n(-c6ccccc6)c5c43)n2)cc1] | WO2008056746 |
| | 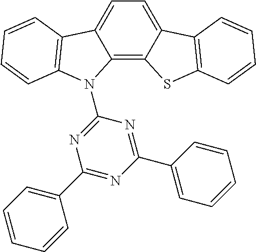 [SMILES: c1ccc(-c2nc(-c3ccccc3)nc(-n3c4ccccc4c4ccc5c6ccccc6sc5c43)n2)cc1] | WO2010107244 |
| Aza-carbazole/ DBT/DBF | 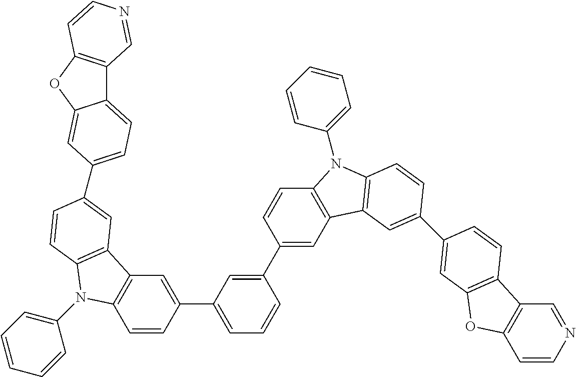 [SMILES: c1ccc(-n2c3ccc(-c4cccc(-c5ccc6c(c5)c5cc(-c7ccc8c(c7)oc7ccncc78)ccc5n6-c5ccccc5)c4)cc3c3cc(-c4ccc5c(c4)oc4ccncc45)ccc32)cc1] | JP2008074939 |
| | 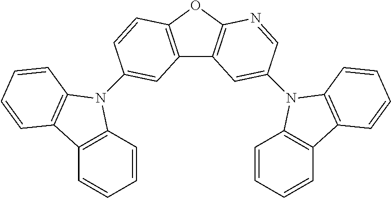 [SMILES: c1ccc2c(c1)c1ccccc1n2-c1ccc2oc3ncc(-n4c5ccccc5c5ccccc54)cc3c2c1] | US20100187984 |
| Polymers (e.g., PVK) | 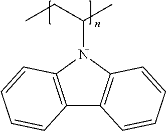 | Appl. Phys. Lett. 77, 2280 (2000) |
| Spirofluorene compounds | 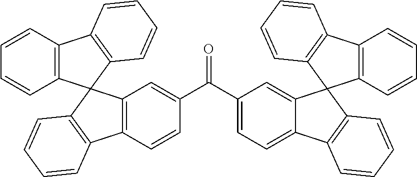 [SMILES: O=C(c1ccc2c(c1)C1(c3ccccc3-c3ccccc31)c1ccccc1-2)c1ccc2c(c1)C1(c3ccccc3-c3ccccc31)c1ccccc1-2] | WO2004093207 |
| Metal phenoxybenzooxazole compounds | 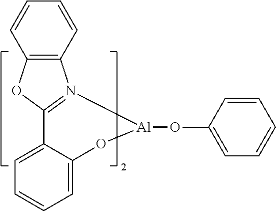 | WO2005089025 |
| | 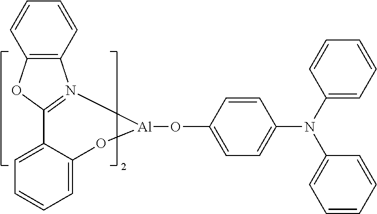 | WO2006132173 |
| | 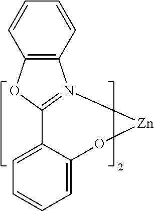 | JP200511610 |
| Spirofluorene- carbazole compounds | 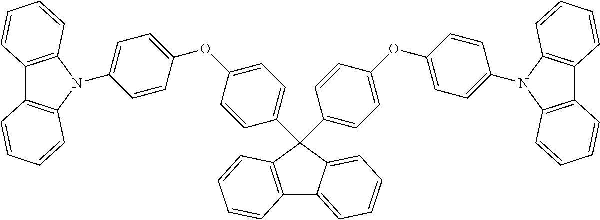 [SMILES: c1ccc2c(c1)-c1ccccc1C2(c1ccc(Oc2ccc(-n3c4ccccc4c4ccccc43)cc2)cc1)c1ccc(Oc2ccc(-n3c4ccccc4c4ccccc43)cc2)cc1] | JP2007254297 |
| | 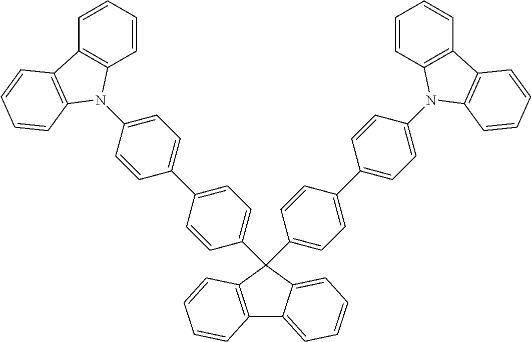 [SMILES: c1ccc2c(c1)-c1ccccc1C2(c1ccc(-c2ccc(-n3c4ccccc4c4ccccc43)cc2)cc1)c1ccc(-c2ccc(-n3c4ccccc4c4ccccc43)cc2)cc1] | JP2007254297 |
| Indolocabazoles | 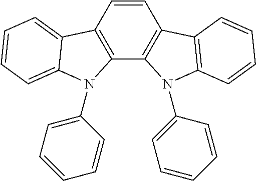 [SMILES: c1ccc(-n2c3ccccc3c3ccc4c5ccccc5n(-c5ccccc5)c4c32)cc1] | WO2007063796 |
| | 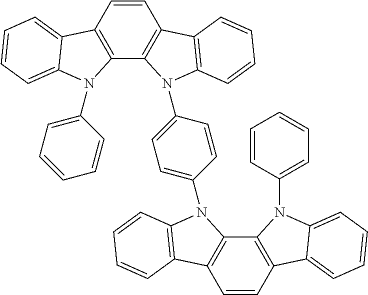 [SMILES: c1ccc(-n2c3ccccc3c3ccc4c5ccccc5n(-c5ccc(-n6c7ccccc7c7ccc8c9ccccc9n(-c9ccccc9)c8c76)cc5)c4c32)cc1] | WO2007063754 |
| 5-member ring electron deficient heterocycles (e.g., triazole, oxadiazole) | 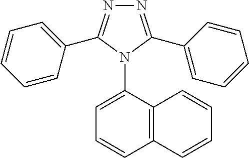 [SMILES: c1ccc(-c2nnc(-c3ccccc3)n2-c2cccc3ccccc23)cc1] | J. Appl. Phys. 90, 5048 (2001) |
| | 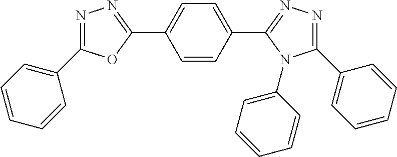 [SMILES: c1ccc(-c2nnc(-c3ccc(-c4nnc(-c5ccccc5)n4-c4ccccc4)cc3)o2)cc1] | WO2004107822 |
| Tetraphenylene complexes | 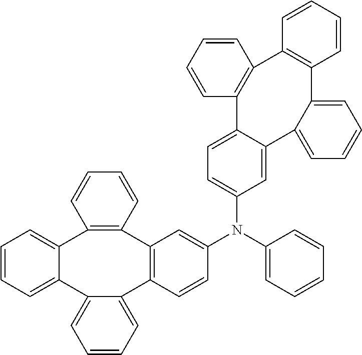 [SMILES: c1ccc(N(c2ccc3c(c2)-c2ccccc2-c2ccccc2-c2ccccc2-3)c2ccc3c(c2)-c2ccccc2-c2ccccc2-c2ccccc2-3)cc1] | US20050112407 |
| Metal phenoxypyridine compounds | 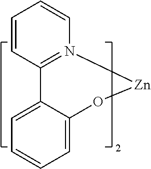 | WO2005030900 |
| Metal coordination complexes (e.g., Zn, Al with N\hat{ }N ligands) | 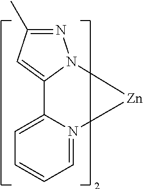 | US20040137268, US20040137267 |

Blue hosts

| | | |
|---|---|---|
| Arylcarbazoles | 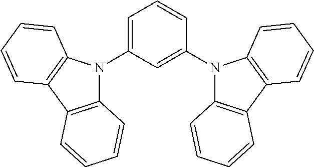 [SMILES: c1cc(-n2c3ccccc3c3ccccc32)cc(-n2c3ccccc3c3ccccc32)c1] | Appl. Phys. Lett, 82, 2422 (2003) |
| | 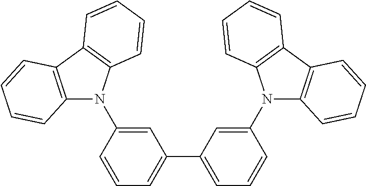 [SMILES: c1cc(-c2cccc(-n3c4ccccc4c4ccccc43)c2)cc(-n2c3ccccc3c3ccccc32)c1] | US20070190359 |
| Dibenzothiophene/ Dibenzofuran- carbazole compounds | 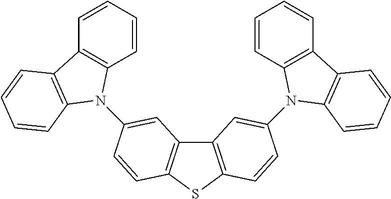 [SMILES: c1ccc2c(c1)c1ccccc1n2-c1ccc2sc3ccc(-n4c5ccccc5c5ccccc54)cc3c2c1] | WO2006114966, US20090167162 |
| | 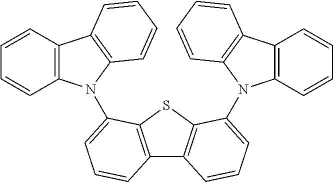 [SMILES: c1cc(-n2c3ccccc3c3ccccc32)c2sc3c(-n4c5ccccc5c5ccccc54)cccc3c2c1] | US20090167162 |
| | 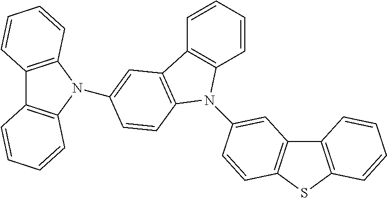 [SMILES: c1ccc2c(c1)sc1ccc(-n3c4ccccc4c4cc(-n5c6ccccc6c6ccccc65)ccc43)cc12] | WO2009086028 |
| | 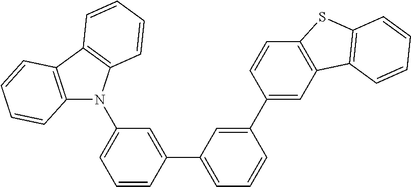 [SMILES: c1cc(-c2cccc(-n3c4ccccc4c4ccccc43)c2)cc(-c2ccc3sc4ccccc4c3c2)c1] | US20090030202, US20090017330 |
| | 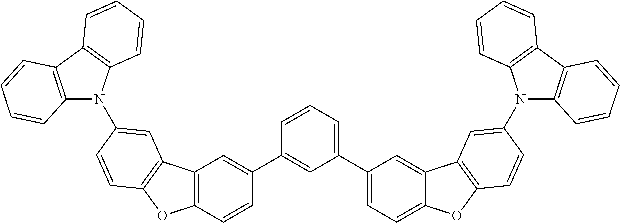 [SMILES: c1cc(-c2ccc3oc4ccc(-n5c6ccccc6c6ccccc65)cc4c3c2)cc(-c2ccc3oc4ccc(-n5c6ccccc6c6ccccc65)cc4c3c2)c1] | US20100084966 |
| Silicon aryl compounds | 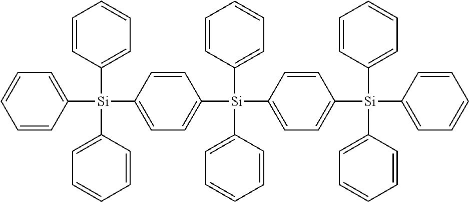 [SMILES: c1ccc([Si](c2ccccc2)(c2ccccc2)c2ccc([Si](c3ccccc3)(c3ccccc3)c3ccc([Si](c4ccccc4)(c4ccccc4)c4ccccc4)cc3)cc2)cc1] | US20050238919 |
| | 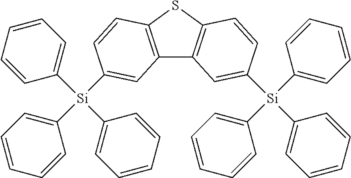 [SMILES: c1ccc([Si](c2ccccc2)(c2ccccc2)c2ccc3sc4ccc([Si](c5ccccc5)(c5ccccc5)c5ccccc5)cc4c3c2)cc1] | WO2009003898 |
| Silicon/ Germanium aryl compounds | 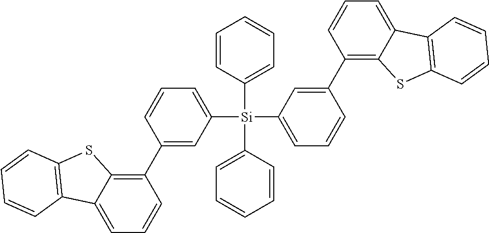 [SMILES: c1ccc([Si](c2ccccc2)(c2cccc(-c3cccc4c3sc3ccccc34)c2)c2cccc(-c3cccc4c3sc3ccccc34)c2)cc1] | EP2034538A |
| Aryl benzoyl ester | 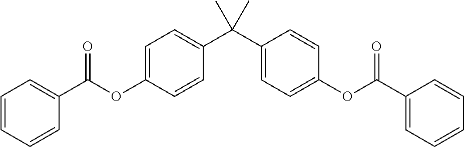 [SMILES: CC(C)(c1ccc(OC(=O)c2ccccc2)cc1)c1ccc(OC(=O)c2ccccc2)cc1] | WO2006100298 |
| Carbazole linked by non- conjugated groups | 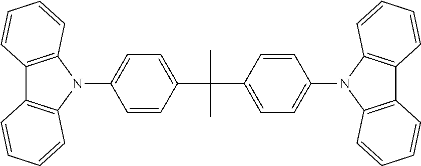 [SMILES: CC(C)(c1ccc(-n2c3ccccc3c3ccccc32)cc1)c1ccc(-n2c3ccccc3c3ccccc32)cc1] | US20040115476 |
| Aza-carbazoles | 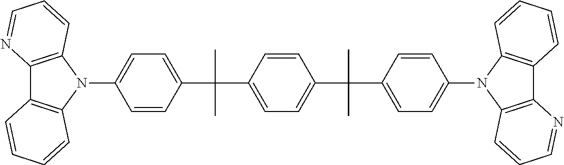 [SMILES: CC(C)(c1ccc(-n2c3ccccc3c3ncccc32)cc1)c1ccc(C(C)(C)c2ccc(-n3c4ccccc4c4ncccc43)cc2)cc1] | US20060121308 |
| High triplet metal organometallic complex | 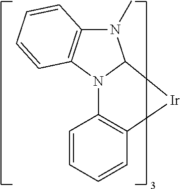 | US7154114 |

Phosphorescent dopants
Red dopants

| | | |
|---|---|---|
| Heavy metal porphyrins (e.g., PtOEP) | 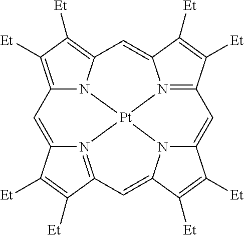 | Nature 395, 151 (1998) |
| Iridium(III) organometallic complexes | 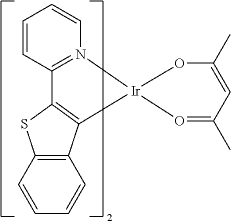 | Appl. Phys. Lett. 78, 1622 (2001) |
| | 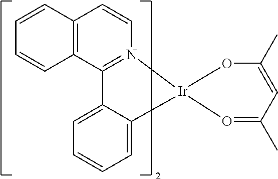 | US2006835469 |
| | 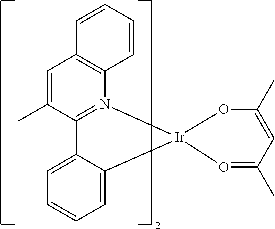 | US2006835469 |
| | 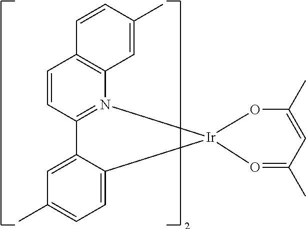 | US20060202194 |
| | 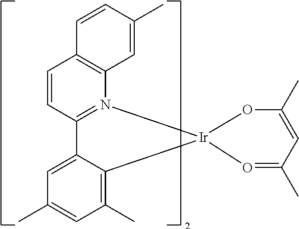 | US20060202194 |
| | 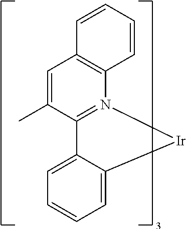 | US20070087321 |
| | 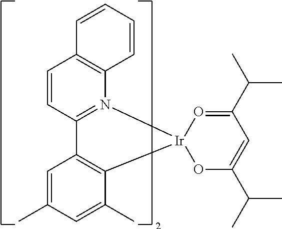 | US20080261076 US20100090591 |
| | 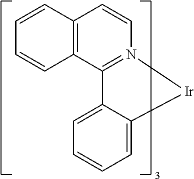 | US20070087321 |
| | 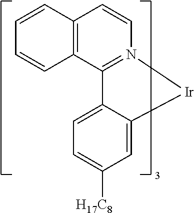 | Adv. Mater. 19, 739 (2007) |
| | 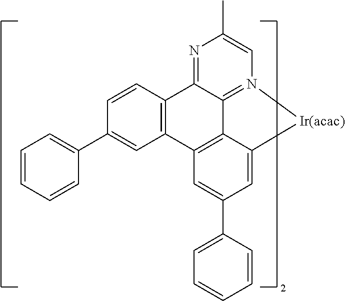 | WO2009100991 |
| | 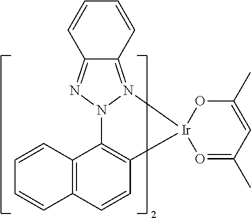 | WO2008101842 |
| | 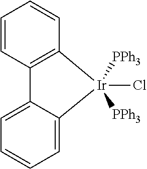 | US7232618 |
| Platinum(II) organometallic complexes | 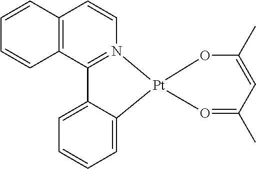 | WO2003040257 |
| | 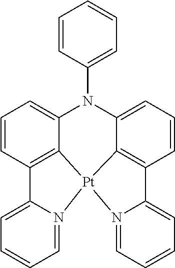 | US20070103060 |
| Osminum(III) complexes | 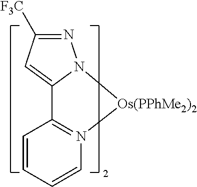 | Chem. Mater. 17, 3532 (2005) |
| Ruthenium(II) complexes | 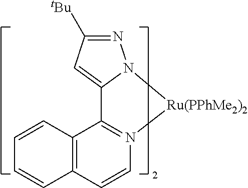 | Adv. Mater. 17, 1059 (2005) |
| Rhenium (I), (II), and (III) complexes | 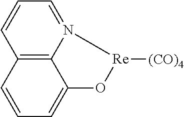 | US20050244673 |

Green dopants

| | | |
|---|---|---|
| Iridium(III) organometallic complexes | 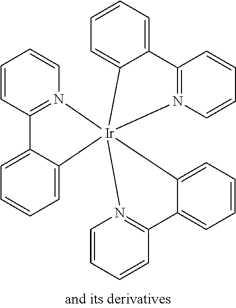 | Inorg. Chem. 40, 1704 (2001) |
| | 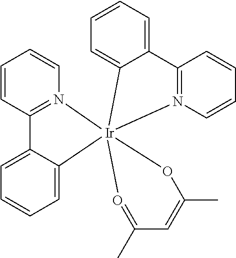 | US20020034656 |
| | 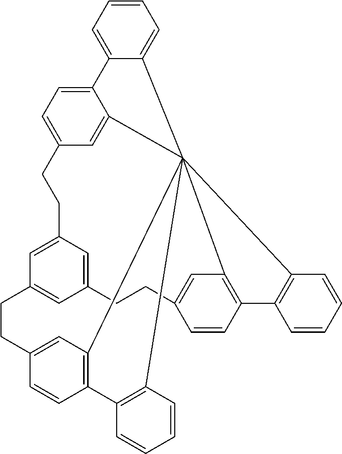 | US7332232 |
| | 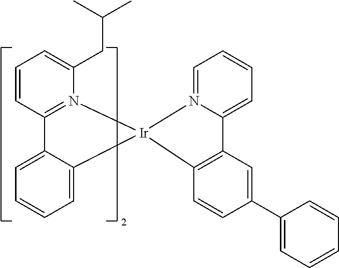 | US20090108737 |
| | 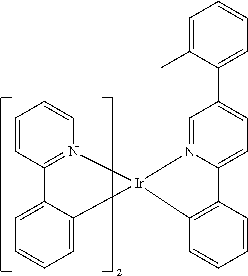 | WO2010028151 |
| | 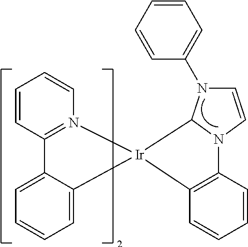 | EP1841834B |
| | 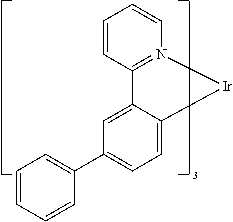 | US20060127696 |
| | 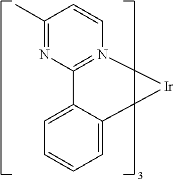 | US20090039776 |
| | 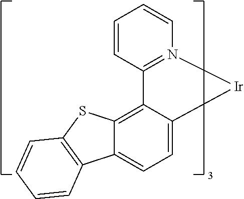 | US6921915 |
| | 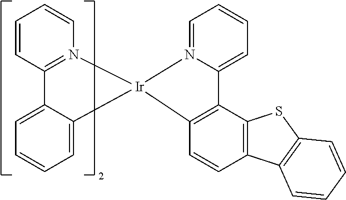 | US20100244004 |
| | 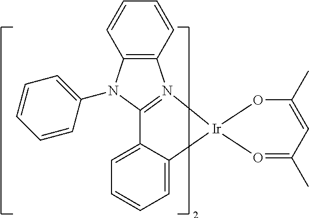 | US6687266 |
| | 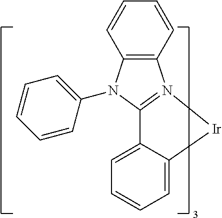 | Chem. Mater. 16, 2480 (2004) |
| | 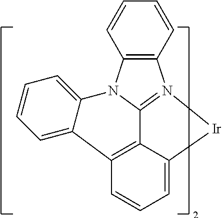 | US20070190359 |
| | 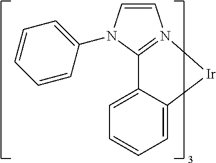 | US20060008670 JP2007123392 |
| | 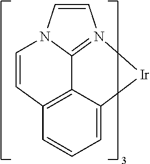 | WO2010086089, WO2011044988 |
| | 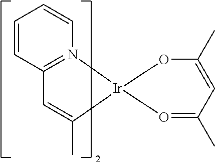 | Adv. Mater. 16, 2003 (2004) |
| | 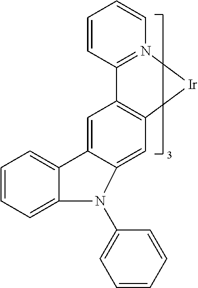 | Angew. Chem. Int. Ed. 2006, 45, 7800 |
| | 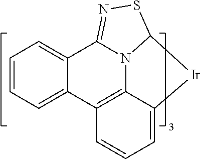 | WO2009050290 |
| | 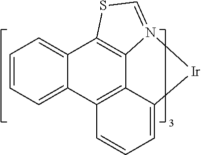 | US20090165846 |
| | 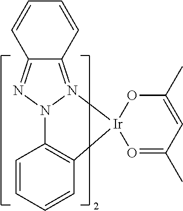 | US20080015355 |
| | 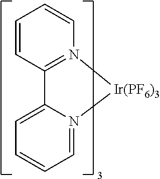 | US20010015432 |
| | 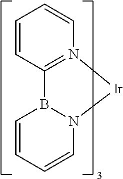 | US20100295032 |
| Monomer for polymeric metal organometallic compounds | 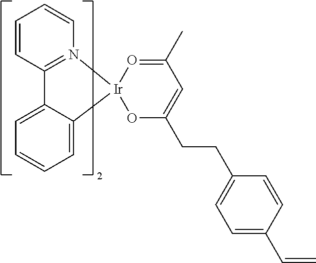 | US7250226, US7396598 |
| Pt(II) organometallic complexes, including polydentated ligands | 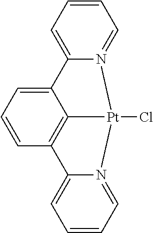 | Appl. Phys. Lett. 86, 153505 (2005) |
| | 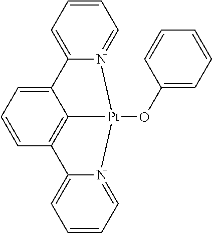 | Appl. Phys. Lett. 86, 153505 (2005) |
| | 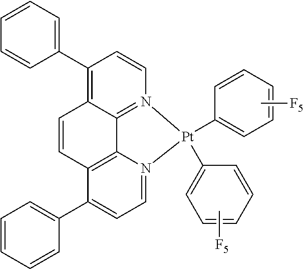 | Chem. Lett. 34, 592 (2005) |
| | 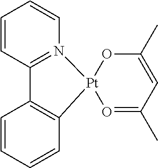 | WO2002015645 |
| | 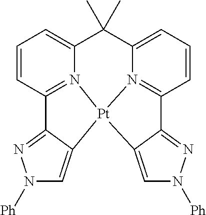 | US20060263635 |
| | 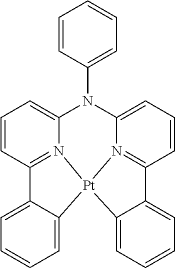 | US20060182992 US20070103060 |
| Cu complexes | 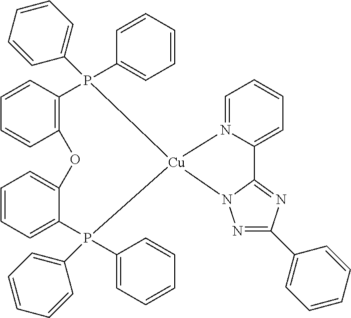 | WO2009000673 |
| | 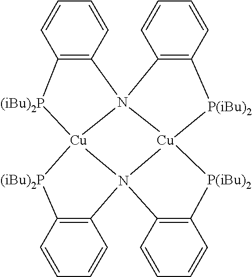 | US20070111026 |
| Gold complexes | 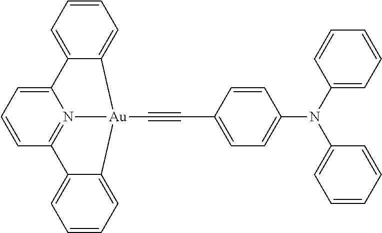 | Chem. Commun. 2906 (2005) |
| Rhenium(III) complexes | 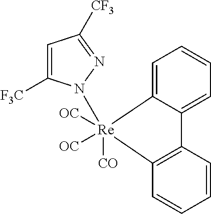 | Inorg. Chem. 42, 1248 (2003) |
| Osmium(II) complexes | 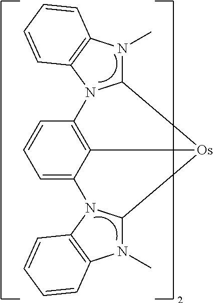 | US7279704 |
| Deuterated organometallic complexes | 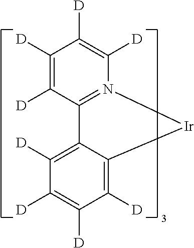 | US20030138657 |
| Organometallic complexes with two or more metal centers | 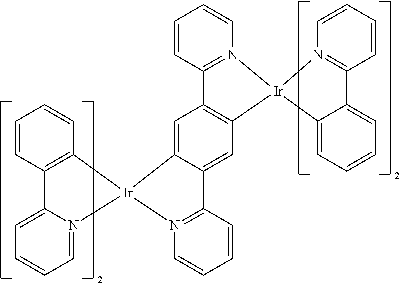 | US20030152802 |
| | 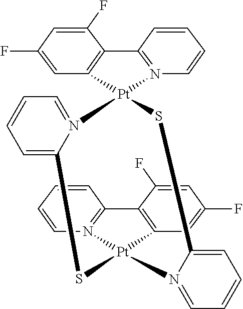 | US7090928 |

Blue dopants

| | | |
|---|---|---|
| Iridium(III) organometallic complexes | 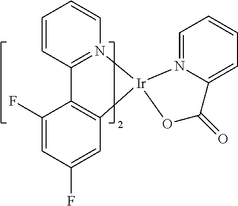 | WO2002002714 |
| | 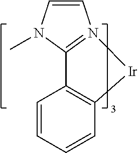 | WO2006009024 |
| | 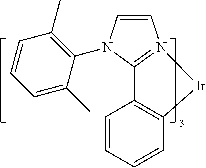 | US20060251923 US20110057559 US20110204333 |
| | 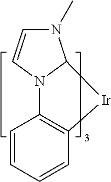 | US7393599, WO2006056418, US20050260441, WO2005019373 |
| | 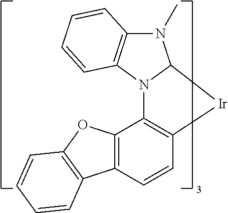 | US7534505 |
| | 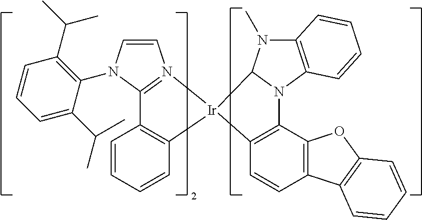 | WO2011051404 |
| | 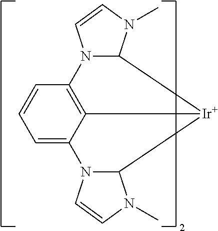 | US7445855 |
| | 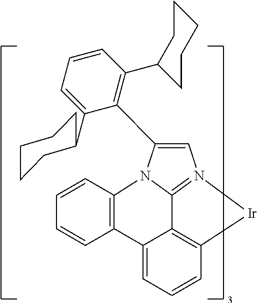 | US20070190359, US20080297033 US20100148663 |
| | 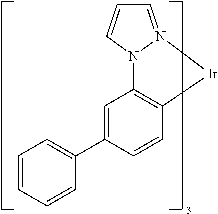 | US7338722 |
| | 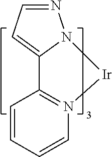 | US20020134984 |
| | 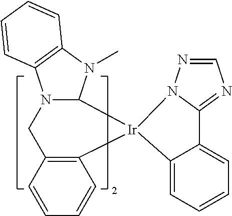 | Angew. Chem. Int. Ed. 47, 1 (2008) |
| | 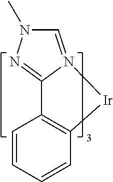 | Chem. Mater. 18, 5119 (2006) |
| | 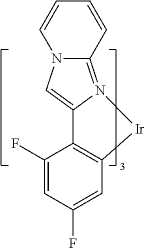 | Inorg. Chem. 46, 4308 (2007) |
| | 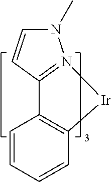 | WO2005123873 |
| | 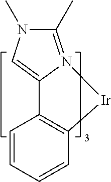 | WO2005123873 |
| | 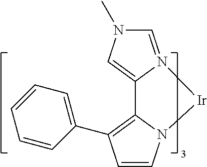 | WO2007004380 |
| | 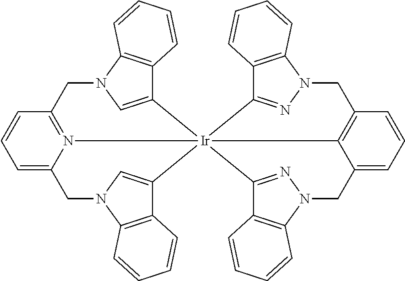 | WO2006082742 |
| Osmium(II) complexes | 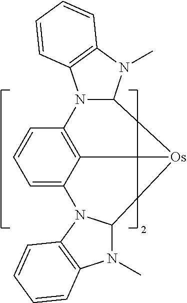 | US7279704 |
| | 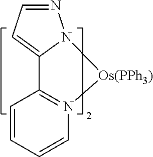 | Organometallics 23, 3745 (2004) |
| Gold complexes | 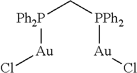 | Appl. Phys. Lett. 74, 1361 (1999) |
| Platinum(II) complexes | 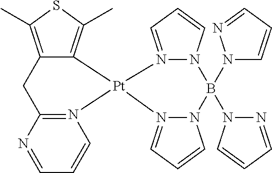 | WO2006098120, WO2006103874 |
| Pt tetradentate complexes with at least one metal- carbene bond | 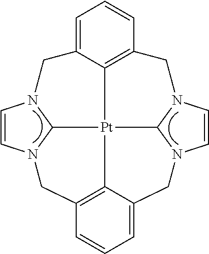 | US7655323 |

Exciton/hole blocking layer materials

| | | |
|---|---|---|
| Bathocuprine compounds (e.g., BCP, BPhen) | 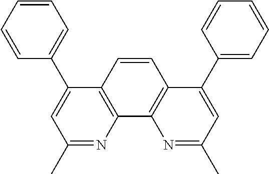 [SMILES: Cc1cc(-c2ccccc2)c2ccc3c(-c4ccccc4)cc(C)nc3c2n1] | Appl. Phys. Lett. 75, 4 (1999) |
| | 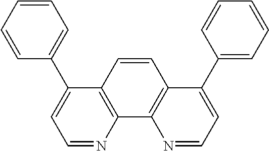 [SMILES: c1ccc(-c2ccnc3c2ccc2c(-c4ccccc4)ccnc23)cc1] | Appl. Phys. Lett. 79, 449 (2001) |
| Metal 8- hydroxyquinolates (e.g., BAlq) | 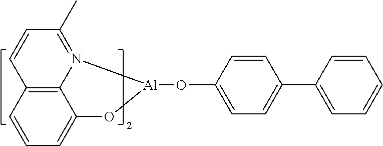 | Appl. Phys. Lett. 81, 162 (2002) |
| 5-member ring electron deficient heterocycles such as triazole, oxadiazole, imidazole, benzoimidazole | 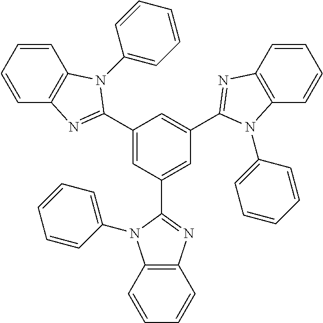 [SMILES: c1ccc(-n2c(-c3cc(-c4nc5ccccc5n4-c4ccccc4)cc(-c4nc5ccccc5n4-c4ccccc4)c3)nc3ccccc32)cc1] | Appl. Phys. Lett. 81, 162 (2002) |
| Triphenylene compounds | 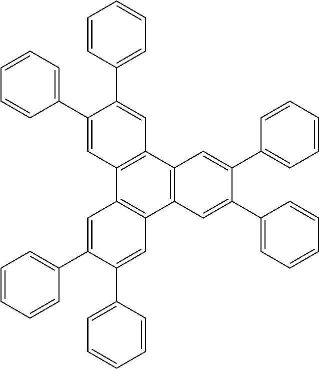 [SMILES: c1ccc(-c2cc3c4cc(-c5ccccc5)c(-c5ccccc5)cc4c4cc(-c5ccccc5)c(-c5ccccc5)cc4c3cc2-c2ccccc2)cc1] | US20050025993 |
| Fluorinated aromatic compounds | 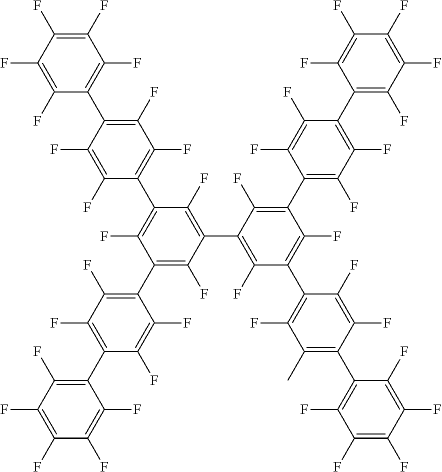 [SMILES: Cc1c(F)c(-c2c(F)c(-c3c(F)c(F)c(-c4c(F)c(F)c(F)c(F)c4F)c(F)c3F)c(F)c(-c3c(F)c(-c4c(F)c(F)c(-c5c(F)c(F)c(F)c(F)c5F)c(F)c4F)c(F)c(-c4c(F)c(F)c(-c5c(F)c(F)c(F)c(F)c5F)c(F)c4F)c3F)c2F)c(F)c(F)c1-c1c(F)c(F)c(F)c(F)c1F] | Appl. Phys. Lett. 79, 156 (2001) |
| Phenothiazine-S- oxide | 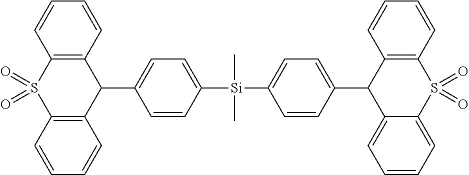 [SMILES: C[Si](C)(c1ccc(C2c3ccccc3S(=O)(=O)c3ccccc32)cc1)c1ccc(C2c3ccccc3S(=O)(=O)c3ccccc32)cc1] | WO2008132085 |
| Silylated five- membered nitrogen, oxygen, sulfur or phosphorus dibenzoheterocycles | 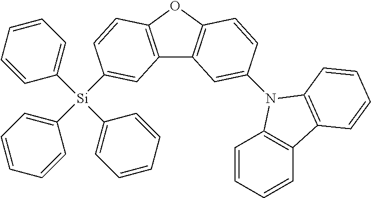 [SMILES: c1ccc([Si](c2ccccc2)(c2ccccc2)c2ccc3oc4ccc(-n5c6ccccc6c6ccccc65)cc4c3c2)cc1] | WO2010079051 |
| Aza-carbazoles | 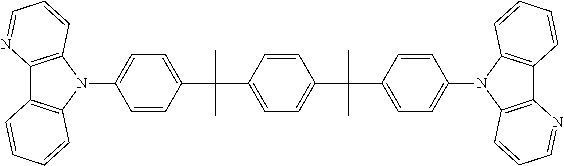 [SMILES: CC(C)(c1ccc(-n2c3ccccc3c3ncccc32)cc1)c1ccc(C(C)(C)c2ccc(-n3c4ccccc4c4ncccc43)cc2)cc1] | US20060121308 |

Electron transporting materials

| | | |
|---|---|---|
| Anthracene- benzoimidazole compounds | 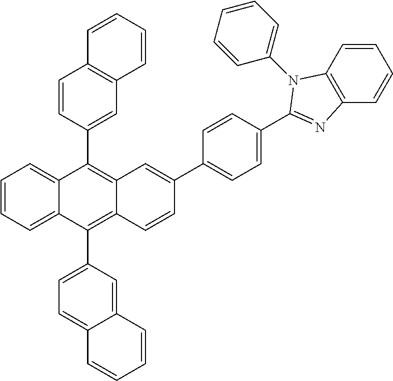 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1] | WO2003060956 |
| | 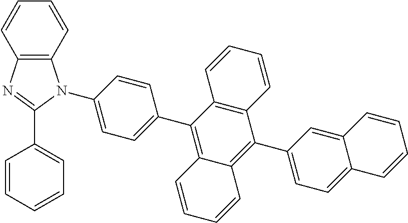 [SMILES: c1ccc(-c2nc3ccccc3n2-c2ccc(-c3c4ccccc4c(-c4ccc5ccccc5c4)c4ccccc34)cc2)cc1] | US20090179554 |
| Aza triphenylene derivatives | 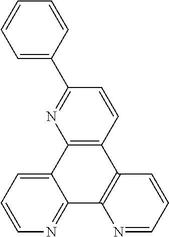 [SMILES: c1ccc(-c2ccc3c4cccnc4c4ncccc4c3n2)cc1] | US20090115316 |
| Anthracene- benzothiazole compounds | 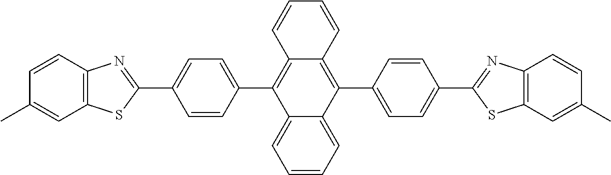 | Appl. Phys. Lett. 89, 063504 (2006) |
| Metal 8- hydroxyquinolates (e.g., Alq₃, Zrq₄) | 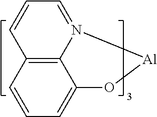 | Appl. Phys. Lett. 51, 913 (1987) US7230107 |
| Metal hydroxybenoquinolates | 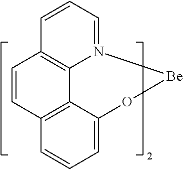 | Chem. Lett. 5, 905 (1993) |
| Bathocuprine compounds such as BCP, BPhen, etc | 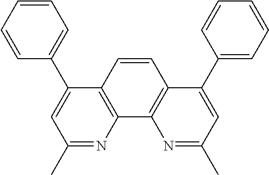 [SMILES: Cc1cc(-c2ccccc2)c2ccc3c(-c4ccccc4)cc(C)nc3c2n1] | Appl. Phys. Lett. 91, 263503 (2007) |
| | 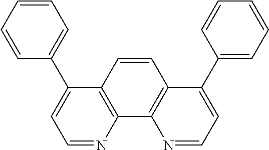 [SMILES: c1ccc(-c2ccnc3c2ccc2c(-c4ccccc4)ccnc23)cc1] | Appl. Phys. Lett. 79, 449 (2001) |
| 5-member ring electron deficient heterocycles (e.g., triazole, oxadiazole, imidazole, benzoimidazole) | 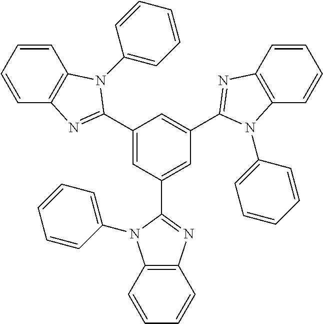 [SMILES: c1ccc(-n2c(-c3cc(-c4nc5ccccc5n4-c4ccccc4)cc(-c4nc5ccccc5n4-c4ccccc4)c3)nc3ccccc32)cc1] | Appl. Phys. Lett. 74, 865 (1999) |
| | 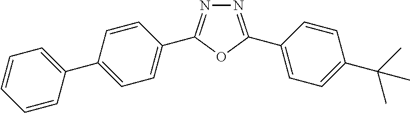 [SMILES: CC(C)(C)c1ccc(-c2nnc(-c3ccc(-c4ccccc4)cc3)o2)cc1] | Appl. Phys. Lett. 55, 1489 (1989) |
| | 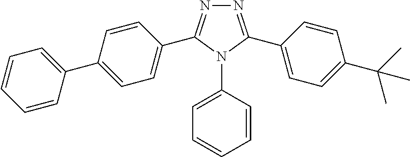 [SMILES: CC(C)(C)c1ccc(-c2nnc(-c3ccc(-c4ccccc4)cc3)n2-c2ccccc2)cc1] | Jpn. J. Apply. Phys. 32, L917 (1993) |
| Silole compounds | 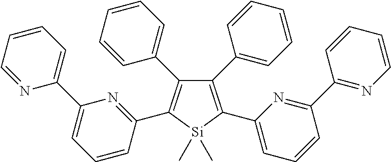 [SMILES: C[Si]1(C)C(c2cccc(-c3ccccn3)n2)=C(c2ccccc2)C(c2ccccc2)=C1c1cccc(-c2ccccn2)n1] | Org. Electron. 4, 113 (2003) |
| Arylborane compounds | 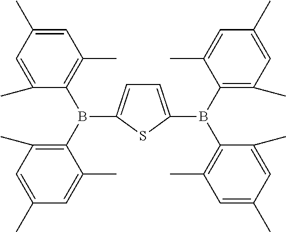 | J. Am. Chem. Soc. 120, 9714 (1998) |
| Fluorinated aromatic compounds | 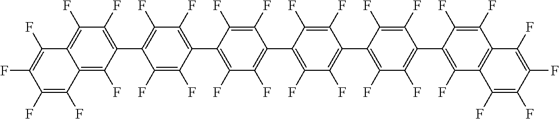 [SMILES: Fc1c(F)c(-c2c(F)c(F)c(-c3c(F)c(F)c4c(F)c(F)c(F)c(F)c4c3F)c(F)c2F)c(F)c(F)c1-c1c(F)c(F)c(-c2c(F)c(F)c(-c3c(F)c(F)c4c(F)c(F)c(F)c(F)c4c3F)c(F)c2F)c(F)c1F] | J. Am. Chem. Soc. 122, 1832 (2000) |
| Fullerene (e.g., C60) | 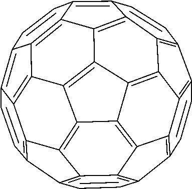 [SMILES: c1cc2c3ccc4c5ccc6c7ccc8c9ccc%10c1c1c2c2c3c4c3c5c6c4c7c8c5c9c%10c1c1c2c3c4c51] | US20090101870 |
| Triazine complexes | 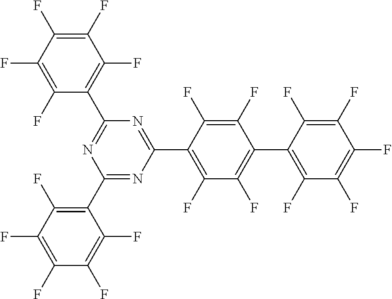 [SMILES: Fc1c(F)c(F)c(-c2nc(-c3c(F)c(F)c(F)c(F)c3F)nc(-c3c(F)c(F)c(-c4c(F)c(F)c(F)c(F)c4F)c(F)c3F)n2)c(F)c1F] | US20040036077 |
| Zn (N\hat{ }N) complexes | 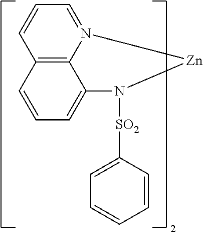 | US6528187 |

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

1. A first device comprising a first organic light emitting device, further comprising:
an anode;
a cathode; and
an emissive layer disposed between the anode and the cathode, said emissive layer comprising a phosphorescent emissive dopant and a host material, the host comprising nanocrystals, wherein at least 50% of ligands bonded to said nanocrystals are compact ligands.

2. The first device according to claim 1, wherein at least 80% of ligands bonded to said nanocrystals are compact ligands.

3. The first device according to claim 2, wherein said compact ligands are organic ligands.

4. The first device according to claim 3, wherein said short-chain organic ligands comprise at least one functional group consisting of carboxylates, amines, thiols, phosphonates, and combinations thereof.

5. The first device according to claim 3, where in the short-chain organic ligands are selected from the group consisting of formic acid, 1,2-ethanedithiol, ethylenediamine, 1,4-benzenedithiol and combinations thereof.

6. The first device according to claim 2, wherein said compact ligands are inorganic ligands.

7. The first device according to claim 6, wherein said inorganic ligands are selected from the group consisting of chalcogenide complexes, simple chalcogenide ions, chalcogenocyanates, halides, tetrafluoroborate, hexafluorophosphate and combinations thereof.

8. The first device according to claim 1, wherein said nanocrystals comprise one or more inorganic materials selected from the group consisting of a sulfide, a selenide, a telluride, an arsenide, a phosphide, a nitride, a carbide, an oxide, a fluoride, an oxysulfide and combinations thereof.

9. The first device according to claim 1, wherein said nanocrystals comprise one or more inorganic materials selected from the group consisting of ZnO, In₂O₃, Ni₂O, MnO, MoS₂, TiO₂, SiC, CdS, CdSe, GaAs, InP, ZnSe, ZnTe, GeS₂, InAs, CdTe, ZnS, CdSeₓS₁₋ₓ, ZnSeₓTe₁₋ₓ, AlₓZn₁₋ₓO, In₂₋ₓSnₓO₃, AlGaAs, CuInS₂, CuInSe₂, NaYF₄, BaTiO₃, SnO₂, SnO_{2-X}F_{X}, SnS₂, Gd₂O₂S, and combinations thereof.

10. The first device according to claim 1, wherein the host material has an energy band gap of less than 4 eV.

11. The first device according to claim 1, wherein said nanocrystals have a size ranging from 1 to 20 nm.

12. The first device according to claim 1, wherein the concentration of the host material in the emissive layer is 10-90 wt-%.

13. The first device according to claim 1, wherein the host material consists essentially of a substance containing at least 70 wt-% inorganic material.

14. The first device according to claim 1, wherein the phosphorescent emissive dopant is an iridium complex, a platinum complex or a combination of both.

15. The first device according to claim 1, wherein the material host has an energy band gap value larger than the triplet energy of the phosphorescent emissive dopant.

16. The first device according to claim 1, wherein the emissive layer further comprises a second host material, a second phosphorescent emissive dopant, or both.

17. The first device according to claim 16, wherein the concentration of the second host material in the emissive layer is at least 10 wt-%.

18. The first device according to claim 1, wherein the emissive layer further comprises a second host material comprising an organic compound selected from the group consisting of triphenylene, dibenzothiophene, aza-dibenzothiophene, dibenzofuran, aza-dibenzofuran, carbazole, aza-carbazole, and combinations thereof.

19. The first device according to claim 18, wherein the second host material comprising the compound selected from the group consisting of: 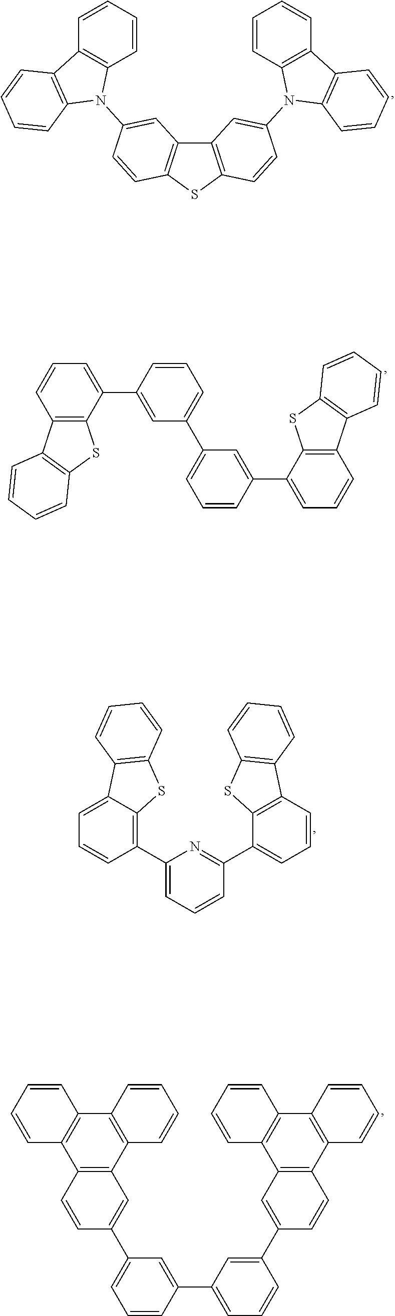 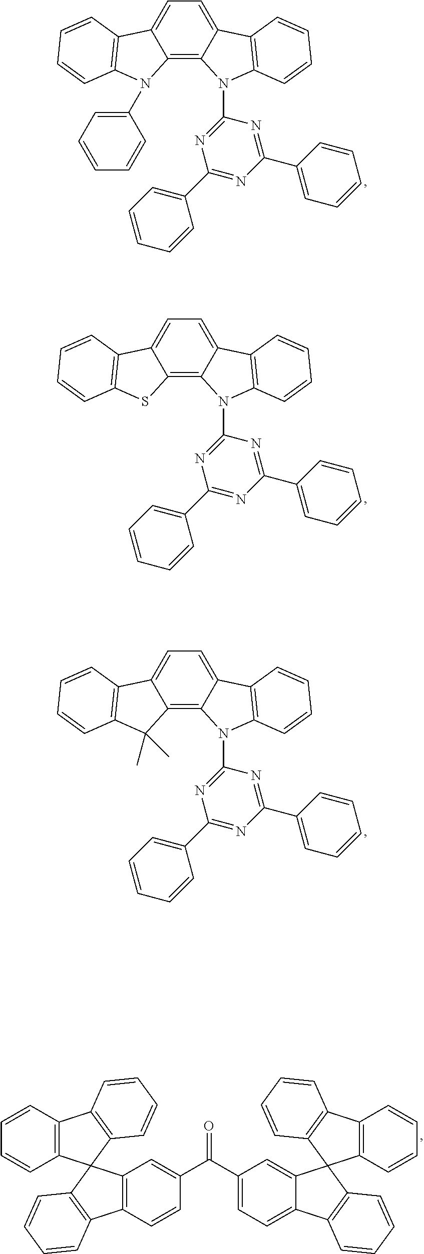 [SMILES: c1ccc(-c2nc(-c3ccccc3)nc(-n3c4ccccc4c4ccc5c6ccccc6n(-c6ccccc6)c5c43)n2)cc1 ; c1ccc(-c2nc(-c3ccccc3)nc(-n3c4ccccc4c4ccc5c6ccccc6sc5c43)n2)cc1 ; CC1(C)c2ccccc2-c2ccc3c4ccccc4n(-c4nc(-c5ccccc5)nc(-c5ccccc5)n4)c3c21 ; O=C(c1ccc2c(c1)C1(c3ccccc3-c3ccccc31)c1ccccc1-2)c1ccc2c(c1)C1(c3ccccc3-c3ccccc31)c1ccccc1-2] 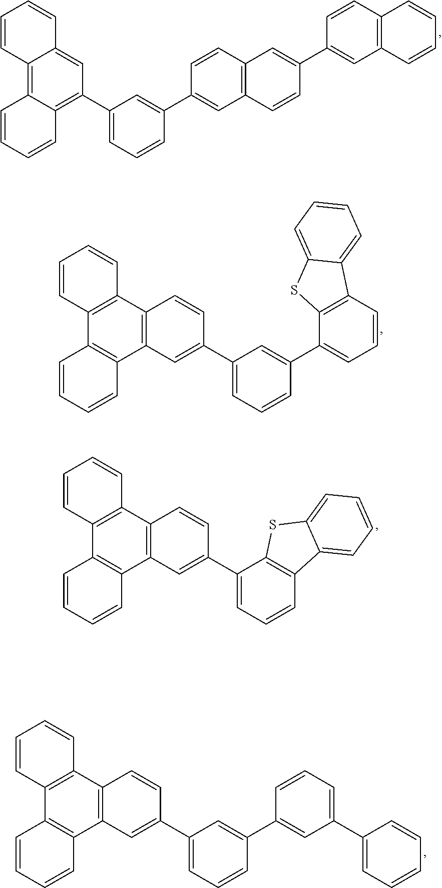
and combinations thereof.

20. The first device according to claim 1, wherein the phosphorescent emissive dopant comprises a transition metal complex having at least one ligand or part of the ligand if the ligand is more than bidentate selected from the group consisting of: 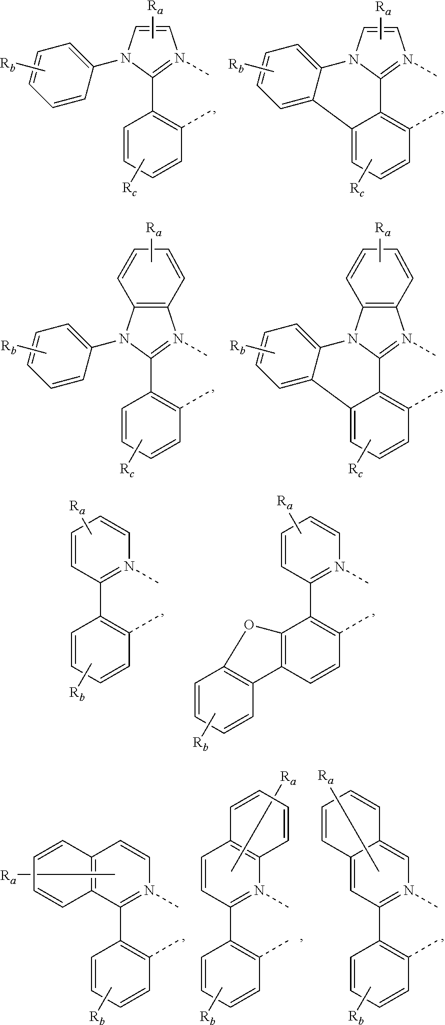 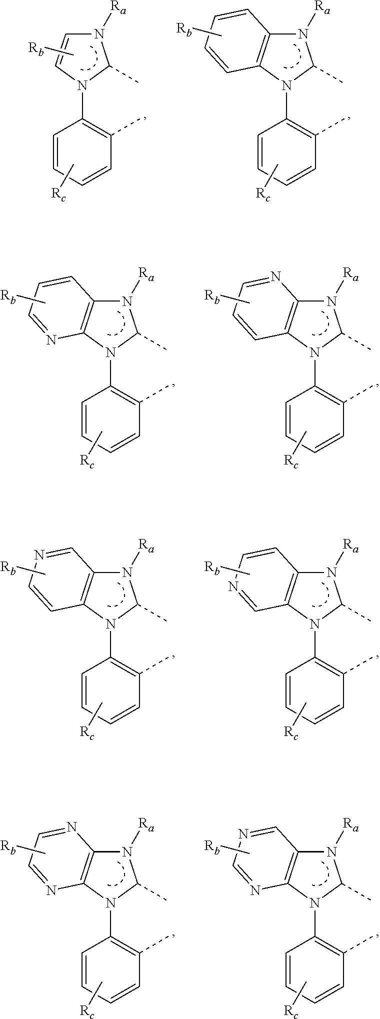 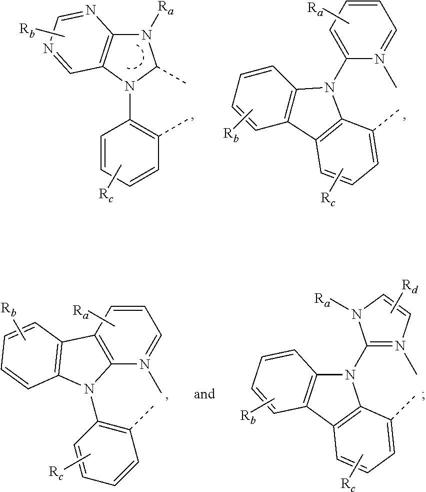
wherein Rₐ, R_{b}, R_{c} and R_{d} may represent mono, di, tri, or tetra substitution, or no substitution;
wherein Rₐ, R_{b}, R_{c}, and R_{d} are independently selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof; and wherein two adjacent substituents of Rₐ, R_{b}, R_{c}, and R_{d} are optionally joined to form a fused ring or form a multidentate ligand.

21. The first device according to claim 1, wherein the first device is a consumer product.

22. The first device according to claim 1, wherein the first device is an organic light-emitting device.

23. The first device according to claim 1, wherein the first device comprises a lighting panel.

24. A first device comprising a first organic light emitting device, further comprising:
an anode;
a cathode; and
an emissive layer disposed between the anode and the cathode, said emissive layer comprising a phosphorescent emissive dopant and a host material, the host comprising nanocrystals, wherein an average interparticle distance between adjacent nanoparticles is ≦1 nm.

25. The first device according to claim 24, wherein at least 50% of ligands bonded to said nanocrystals are compact ligands.

26. The first device according to claim 25, wherein said compact ligands are organic ligands.

27. The first device according to claim 26, wherein said short-chain organic ligands comprise at least one functional group consisting of carboxylates, amines, thiols, phosphonates, and combinations thereof.

28. The first device according to claim 26, where in the short-chain organic ligands are selected from the group consisting of formic acid, 1,2-ethanedithiol, ethylenediamine, 1,4-benzenedithiol and combinations thereof.

29. The first device according to claim 25, wherein said compact ligands are inorganic ligands.

30. The first device according to claim 29, wherein said inorganic ligands are selected from the group consisting of chalcogenide complexes, simple chalcogenide ions, chalcogenocyanates, halides, tetrafluoroborate, hexafluorophosphate and combinations thereof.

31. The first device according to claim 24, wherein said nanocrystals comprise one or more inorganic materials selected from the group consisting of a sulfide, a selenide, a telluride, an arsenide, a phosphide, a nitride, a carbide, an oxide, a fluoride, an oxysulfide, and combinations thereof.

32. The first device according to claim 24, wherein said nanocrystals comprise one or more inorganic materials selected from the group consisting of ZnO, In₂O₃, NiO, MnO, MoS₂, TiO₂, SiC, CdS, CdSe, GaAs, InP, ZnSe, ZnTe, GeS₂, InAs, CdTe, ZnS, CdSeₓS₁₋ₓ, ZnSeₓTe₁₋ₓ, AlₓZn₁₋ₓO, In₂₋ₓSnₓO₃, AlGaAs, CuInS₂, CuInSe₂, NaYF₄, BaTiO₃, SnO₂, SnO₂₋ₓFₓ, SnS₂, Gd₂O₂S, and combinations thereof.

33. The first device according to claim 24, wherein the host material has an energy band gap of less than 4 eV.

34. The first device according to claim 24, wherein said nanocrystals have a size ranging from 1 to 20 nm.

35. The first device according to claim 24, wherein the concentration of the host material in the emissive layer is 10-90 wt-%.

36. The first device according to claim 24, wherein the host material consists essentially of a substance containing at least 70 wt-% inorganic material.

37. The first device according to claim 24, wherein the phosphorescent emissive dopant is an iridium complex, a platinum complex or a combination of both.

38. The first device according to claim 24, wherein the material host has an energy band gap value larger than the triplet energy of the phosphorescent emissive dopant.

39. The first device according to claim 24, wherein the emissive layer further comprises a second host material, a second phosphorescent emissive dopant, or both.

40. The first device according to claim 39, wherein the concentration of the second host material in the emissive layer is at least 10 wt-%.

41. The first device according to claim 24, wherein the emissive layer further comprises a second host material comprising an organic compound selected from the group consisting of triphenylene, dibenzothiophene, aza-dibenzothiophene, dibenzofuran, aza-dibenzofuran, carbazole, aza-carbazole, and combinations thereof.

42. The first device according to claim 41, wherein the second host material comprising the compound selected from the group consisting of: 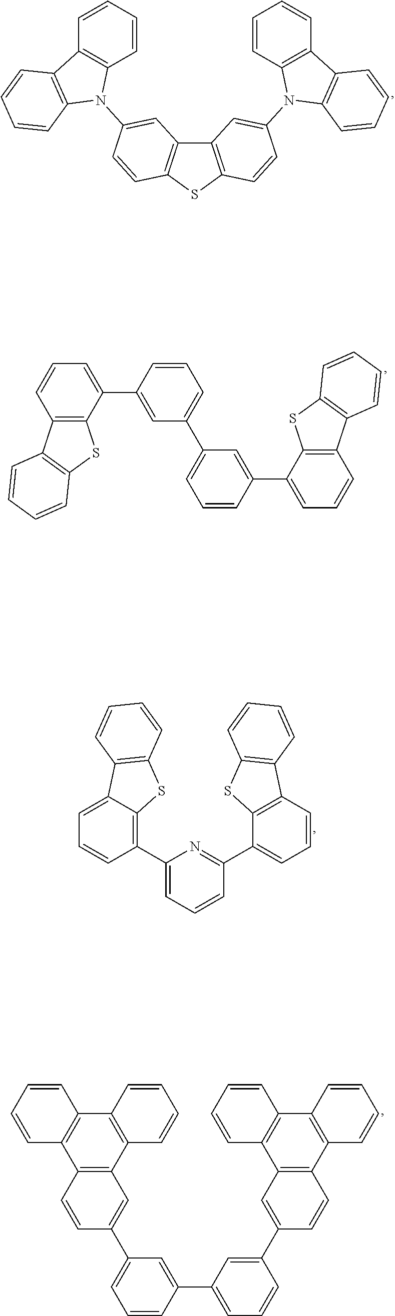 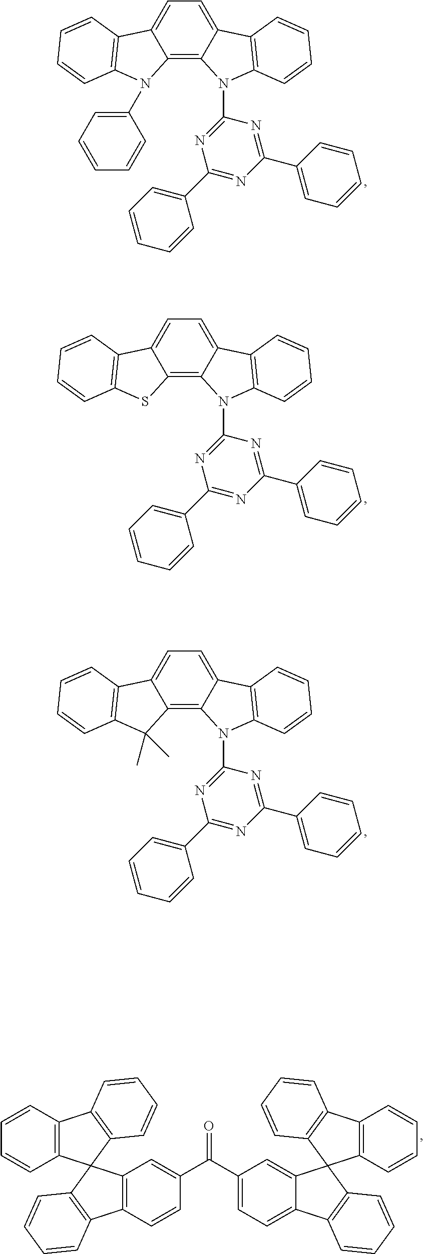 [SMILES: c1ccc(-c2nc(-c3ccccc3)nc(-n3c4ccccc4c4ccc5c6ccccc6n(-c6ccccc6)c5c43)n2)cc1 ; c1ccc(-c2nc(-c3ccccc3)nc(-n3c4ccccc4c4ccc5c6ccccc6sc5c43)n2)cc1 ; CC1(C)c2ccccc2-c2ccc3c4ccccc4n(-c4nc(-c5ccccc5)nc(-c5ccccc5)n4)c3c21 ; O=C(c1ccc2c(c1)C1(c3ccccc3-c3ccccc31)c1ccccc1-2)c1ccc2c(c1)C1(c3ccccc3-c3ccccc31)c1ccccc1-2] 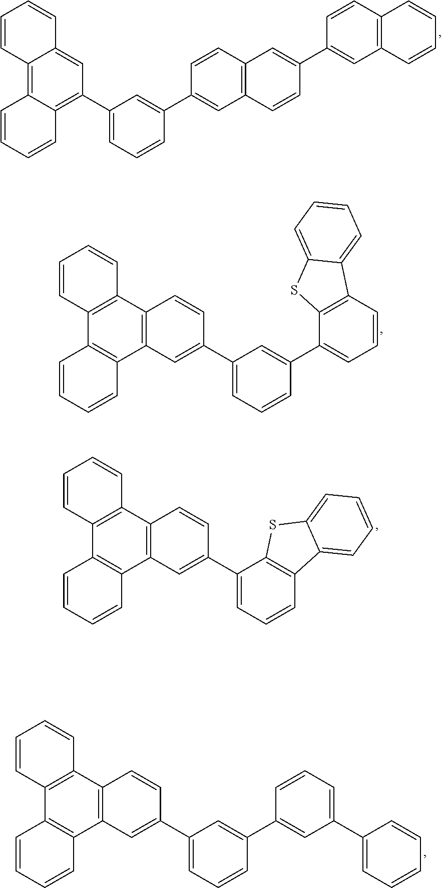
and combinations thereof.

43. The first device according to claim 24, wherein the phosphorescent emissive dopant comprises a transition metal complex having at least one ligand or part of the ligand if the ligand is more than bidentate selected from the group consisting of: 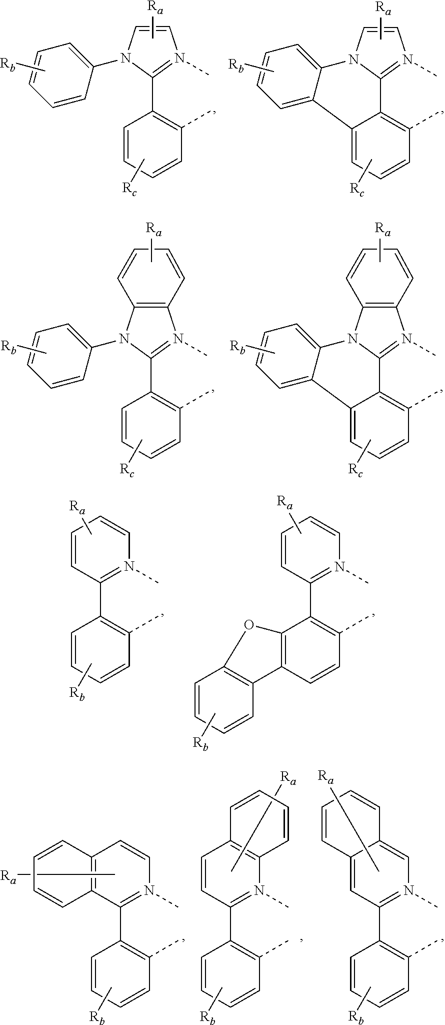 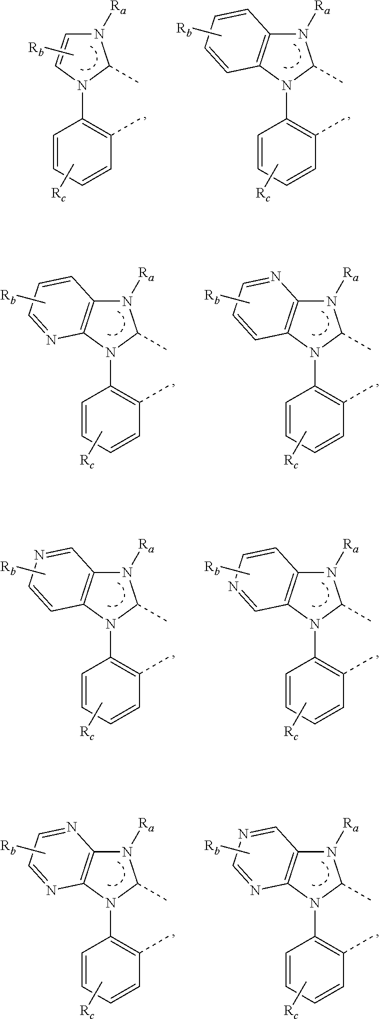 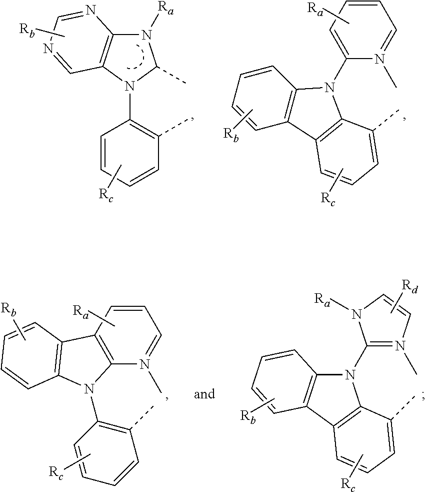
wherein Rₐ, R_{b}, R_{c}, and R_{d} may represent mono, di, tri, or tetra substitution, or no substitution;
wherein Rₐ, R_{b}, R_{c}, and R_{d} are independently selected from the group consisting of hydrogen, deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acids, ester, nitrile, isonitrile, sulfanyl, sulfinyl, sulfonyl, phosphino, and combinations thereof; and wherein two adjacent substituents of Rₐ, R_{b}, R_{c}, and R_{d} are optionally joined to form a fused ring or form a multidentate ligand.

44. The first device according to claim 24, wherein the first device is a consumer product.

45. The first device according to claim 24, wherein the first device is an organic light-emitting device.

46. The first device according to claim 24, wherein the first device comprises a lighting panel.

47. A method of making a first organic light emitting device comprising:
depositing a first electrode layer over a substrate;
forming an emissive layer over said first electrode layer, said emissive layer comprising a phosphorescent emissive dopant and a nanocrystal host material; and
depositing a second electrode layer over said emissive layer, wherein said emissive layer is between said first electrode layer and said second electrode layer, wherein at least 50% of the ligands bonded to said nanocrystals are compact ligands.

48. The method according to claim 47, wherein said forming an emissive layer comprising replacing long-chain organic ligands bonded to the nanocrystal host material with compact ligands to form modified nanocrystal host material in which at least 50% of the ligands bonded to said nanocrystals are compact ligands.

49. The method according to claim 48, wherein said replacing is accomplished by a solution-phase ligand-exchange process.

50. The method according to claim 49, wherein said forming an emissive layer comprising:
dispersing said modified nanocrystal host material in a polar solvent; and
depositing a layer of said modified nanocrystal host material over said first electrode layer by a solution processing.

51. The method according to claim 47, wherein said forming an emissive layer comprises:
depositing a solid film of said nanocrystal host material over said first electrode layer;
immersing said solid film in a solution containing compact ligands, thereby replacing any long-chain organic ligands coupled to the nanocrystal host material with compact ligands to form a modified nanocrystal layer; and
diffusing said phosphorescent emissive dopant into said modified nanocrystal host material by immersing the modified nanocrystal host material layer in a solution containing said phosphorescent emissive dopant.

52. The method according to claim 47, wherein said host material has an energy band gap of less than 4 eV.

53. The method according to claim 47, wherein said forming an emissive layer comprises:
co-depositing a solid film of said nanocrystal host material and phosphorescent emissive dopant over said first electrode layer; and
immersing said solid film in a solution containing compact ligands, thereby replacing any long-chain organic ligands coupled to the nanocrystal host material with compact ligands to form a modified nanocrystal layer.
